(19) United States
(12) Patent Application Publication
(10) Pub. No.: US 2026/0206144 A1
(43) Pub. Date: Jul. 16, 2026

(54) CIRCUIT BOARD, AND SEMICONDUCTOR PACKAGE COMPRISING SAME

(71) Applicant: LG INNOTEK CO., LTD., Seoul (KR)

(72) Inventors: Won Suk JUNG, Seoul (KR); Bung Suek OH, Seoul (KR)

(73) Assignee: LG INNOTEK CO., LTD., Seoul (KR)

(21) Appl. No.: 19/137,924

(22) PCT Filed: Dec. 15, 2023
(86) PCT No.: PCT/KR2023/020805

§ 371 Date: Jun. 11, 2025

(30) Foreign Application Priority Data
Dec. 15, 2022 (KR) 10-2022-0176360

(51) Int. Cl. H05K 1/185; H05K 1/11; H05K 1/181; H05K 3/34; H05K 3/40; H10W 90/10

(52) U.S. Cl. CPC H05K 1/186; H05K 1/113; H05K 1/181; H05K 3/34; H05K 3/4007; H05K 2201/09381; H05K 2201/0939; H05K 2201/09827; H10W 90/10

(57) ABSTRACT

A circuit board according to an embodiment includes a first insulating layer including a cavity; a connection member disposed in the cavity; and a second insulating layer disposed on the connection member and including a material different from a material of the first insulating layer, and wherein a width of the second insulating layer is larger than a width of the connection member.

### TECHNICAL FIELD

An embodiment relates to a circuit board and a semiconductor package comprising the same.

### BACKGROUND ART

As performances of electric/electronic products progresses, technologies for disposing a greater number of semiconductor devices on a semiconductor package circuit board of a limited size are being proposed and studied. However, since a general semiconductor package is based on mounting a single semiconductor device, there is a limit to obtaining a desired performance.

Accordingly, a semiconductor package that mounts a plurality of semiconductor devices using a plurality of circuit boards has been recently provided. This semiconductor package has a structure in which a plurality of semiconductor devices are connected to each other in a horizontal direction and/or a vertical direction on the circuit board. Accordingly, the semiconductor package has the advantage of efficiently using a mounting area of the semiconductor devices and transmitting high-speed signals through a short signal transmission path between the semiconductor devices.

Due to these advantages, the semiconductor package as described above is widely applied to mobile devices, etc.

In addition, semiconductor packages applied to products that provide the Internet of Things (IoT), autonomous vehicles, and high-performance servers are expanding a concept to semiconductor chiplets as a number of semiconductor devices and/or a size of each semiconductor device increases in accordance with a trend of high integration, or as functional parts of the semiconductor devices are divided.

Accordingly, an intercommunication between semiconductor devices and/or semiconductor chiplets is becoming important, and accordingly, there is a trend to dispose an interposer between the circuit board of the semiconductor package and the semiconductor devices.

An interposer can function as a redistribution layer that gradually increases a width or depth of a circuit pattern from the semiconductor device to the semiconductor package in order to facilitate the intercommunication between the semiconductor devices and/or semiconductor chiplets, or to interconnect the semiconductor devices and the semiconductor package circuit board, thereby smoothly transmitting electrical signals between the semiconductor device and the semiconductor package circuit board having a relatively large circuit pattern compared to the circuit pattern of the semiconductor device.

Meanwhile, a package circuit board and/or interposer applied to a semiconductor package may be provided with a connection member connected to a semiconductor device and/or a semiconductor chip-let. The connection member functions to horizontally connect a plurality of semiconductor devices and/or semiconductor chip-lets. Accordingly, the connection member may be embedded in the package circuit board and/or interposer. At this time, the package circuit board and/or interposer may be provided with a plurality of bump portions connected to the semiconductor device and/or the semiconductor chip-let. The bump portion may include a first bump that does not overlap with the connection member in a vertical direction, and a second bump that overlaps with the connection member in the vertical direction and overlaps with the first bump in a horizontal direction.

At this time, the first bump and the second bump may have different widths along the horizontal direction and/or different thicknesses along the vertical direction. That is, the width and/or thickness of the second bump may depend on a width of a pad provided on the connection member and the height of the upper surface of the pad, but the width and height of the first bump are not dependent on the width and/or height of the pad provided on the connection member. That is, when the integration of the number of I/O (Input and Output) terminals of the connection member increases, the amount of current generated during plating of the first and second bumps differs depending on a diameter and a density of via holes of an insulating layer and/or a protective layer disposed on the pad of the connection member, and accordingly, the width of the second bump may differ from the width of the first bump.

Therefore, the first and second bumps according to a prior art may have a height deviation due to a difference in width and/or thickness between them. In addition, when a height deviation occurs between the first and second bumps, a problem may occur in which the semiconductor device and/or the semiconductor chip-let is not stably mounted on the first and second bumps. As a result, there may be a problem that the operating characteristics, reliability, and yield of the semiconductor device and/or the semiconductor chip-let are deteriorated.

### DISCLOSURE

### Technical Problem

An embodiment provides a circuit board having a new structure and a semiconductor package including the same.

In addition, the embodiment provides a circuit board and a semiconductor package including a connection member embedded in the circuit board.

In addition, the embodiment provides a circuit board and a semiconductor package that can minimize a height deviation between a plurality of electrode parts connected to a plurality of semiconductor devices.

In addition, the embodiment provides a circuit board and a semiconductor package including the same, in which a surface of an upper metal layer disposed on a plurality of electrode parts can have a uniform height.

In addition, the embodiment provides a circuit board and a semiconductor package that can solve electrical and/or mechanical reliability problems caused by differences in coefficient of thermal expansions between an insulating layer of the circuit board and an connection member.

In addition, the embodiment provides a circuit board capable of improving an adhesion between multiple insulating layers, electrode parts, and upper metal layers, and a semiconductor package including the same.

In addition, the embodiment provides a circuit board and a semiconductor package that can prevent an intermetallic compound (IMC) between a conductive adhesive and a conductive metal layer from spreading to a bump part.

Technical problems to be solved by the proposed embodiments are not limited to the above-mentioned technical problems, and other technical problems not mentioned may be clearly understood by those skilled in the art to which the embodiments proposed from the following descriptions belong.

### Technical Solution

A circuit board according to an embodiment comprises a first insulating layer including a cavity; a connection member disposed in the cavity; and a second insulating layer disposed on the connection member and including a material different from a material of the first insulating layer, wherein a width of the second insulating layer is larger than a width of the connection member.

In addition, the second insulating layer includes a non-conductive adhesive material.

In addition, an upper surface of the first insulating layer and the upper surface of the second insulating layer have a step.

In addition, the upper surface of the second insulating layer is positioned lower than the upper surface of the first insulating layer.

In addition, the circuit board further comprises a third insulating layer disposed on the first insulating layer and the second insulating layer, wherein a lower surface of the third insulating layer includes a first lower surface in contact with the upper surface of the first insulating layer, and a second lower surface in contact with the upper surface of the second insulating layer, and wherein the first and second lower surfaces of the third insulating layer have a step.

In addition, the circuit board further comprises a bump part including a first bump disposed on the first insulating layer and a second bump disposed on the second insulating layer, wherein the first bump does not overlap the connection member in a vertical direction, and wherein the second bump overlaps the connection member in the vertical direction and overlaps the first bump in a horizontal direction.

In addition, at least one of upper and lower surfaces of the first bump is positioned on a same plane as at least one of upper and lower surfaces of the second bump.

In addition, the connection member includes an insulating member; a pad part disposed on the insulating member; and a bonding part disposed on the pad part and electrically connecting the second bump and the pad part, and wherein the second insulating layer embeds the pad part and the bonding part.

In addition, the second insulating layer includes an extension part extending toward a side surface of the insulating member of the connection member and covering at least a portion of the side surface of the insulating member.

In addition, a width of the second bump in a horizontal direction is smaller than a width of the first bump in the horizontal direction.

In addition, the first bump is disposed on a first concave part provided on an upper surface of the first insulating layer, an upper surface of the first bump is positioned higher than an upper surface of the first insulating layer, and the first bump includes a first slope whose width increases toward a lower surface of the first insulating layer, and the second bump is disposed on a second concave part provided on an upper surface of the second insulating layer, an upper surface of the second bump is positioned higher than an upper surface of the second insulating layer, and the second bump includes a second slope whose width increases toward a lower surface of the second insulating layer.

In addition, the first slope and the second slope are inclined in a same direction and have a same angle.

In addition, the upper metal layer further includes a first upper metal layer disposed on the first bump and a second upper metal layer disposed on the second bump.

In addition, the first slope of the first bump has a first portion overlapping the first insulating layer in a horizontal direction and spaced apart from an inner wall of the first concave part of the first insulating layer, and the second slope of the second bump has a second portion overlapping the first insulating layer in a horizontal direction and spaced apart from an inner wall of the first concave part of the first insulating layer.

In addition, the third insulating layer is disposed on the first insulating layer and the second insulating layer, and contacts the first portion of the first bump and the second portion of the second bump.

In addition, the first upper metal layer protrudes on the third insulating layer while contacting the first portion of the first bump, and the second upper metal layer protrudes on the third insulating layer while contacting the second portion of the second bump.

Meanwhile, a semiconductor package of the embodiment comprises the circuit board described above, and a first semiconductor device disposed on a portion of the first upper metal layer of the circuit board and a portion of the second upper metal layer; and a second semiconductor device disposed on a remaining portion of the first upper metal layer and a remaining portion of the second upper metal layer.

### Advantageous Effects

The circuit board of the embodiment and the semiconductor package comprising the same include a first insulating layer including a cavity, a connection member disposed in the cavity, and a second insulating layer disposed on the connection member. The second insulating layer can stably fix the connection member while relieving thermal stress acting on the semiconductor package, thereby minimizing damage transmitted to the connection member. Through this, the embodiment can prevent thermal stress from being transmitted to the connection member through the second insulating layer. For example, the second insulating layer can serve as a buffer to buffer stress. Through this, the embodiment can stably couple the connection member to the semiconductor package, thereby improving physical reliability and mechanical reliability of the connection member.

Specifically, the second insulating layer is provided to surround a pad part of the connection member and a bonding part disposed on the pad part. In addition, the second insulating layer is provided to surround at least a portion of the bump part disposed on the bonding part. Through this, the second insulating layer of the embodiment functions to buffer stress transmitted to the bump part, the pad part, and the bonding part. Therefore, the embodiment prevents cracks from occurring in the bonding part due to stress. Through this, the embodiment can improve the electrical connection reliability between the pad part, the bonding part, and the bump part. Therefore, the embodiment can stably connect a plurality of semiconductor devices by the connection member, thereby improving the operational reliability of the plurality of semiconductor devices.

In addition, a width of the second insulating layer in a horizontal direction is larger than a width of the connection member in the horizontal direction. Through this, the embodiment can maximize the effect of the buffer function through the second insulating layer, thereby further improving the physical reliability and electrical reliability of the semiconductor package.

In addition, the second insulating layer can include an extension part. In this case, the extension part of the second insulating layer can extend toward a side surface of the connection member. For example, the extension part of the second insulating layer can cover at least a part of the side surface of the connection member. Through this, the embodiment can enable the connection member to be more stably disposed in the cavity, and further minimize the stress transmitted to the connection member. In addition, when air is filled around the side surface of the connection member, the air may expand due to heat generated from the semiconductor device or the semiconductor package, which may cause mechanical damage such as cracks in the semiconductor package. Therefore, if the second insulating layer does not include the extension part, the side surface of the connection member can be covered with another material to improve the operational reliability.

Meanwhile, the second insulating layer can have a step with the first insulating layer. For example, an upper surface of the second insulating layer can be positioned lower than an upper surface of the first insulating layer. Through this, the embodiment can improve a contact area with the third insulating layer disposed on the first insulating layer and the second insulating layer, thereby solving a problem of the third insulating layer being peeled off from the first insulating layer and/or the second insulating layer. In addition, the first insulating layer and the second insulating layer can have different coefficients of thermal expansion, and thus at least one can expand or contract more than at least the other. At this time, the embodiment can solve the problem of peeling between the first insulating layer and the second insulating layer caused by expansion or contraction by making the upper surface of the second insulating layer and the upper surface of the first insulating layer have a step, thereby improving the mechanical reliability of the semiconductor package.

In addition, the semiconductor package of the embodiment includes a bump part disposed on the first and second insulating layers. The bump part includes a first bump protruding on the first insulating layer while penetrating at least a portion of the first insulating layer. In addition, the bump part includes a second bump protruding on the second insulating layer while penetrating at least a portion of the second insulating layer. At this time, a width of the second bump in the horizontal direction may be smaller than a width of the first bump in the horizontal direction. That is, at least a portion of the second bump may be embedded in the second insulating layer, thereby making the width of the second bump smaller than the width of the first bump. Through this, the embodiment may reduce a pitch of the pad part provided in the connection member, thereby reducing a volume of the connection member. Therefore, the embodiment may reduce a volume of the semiconductor package.

In addition, a side surface of the bump part including the first and second bumps may include a first slope that is adjacent to the upper surface of the bump part and increases in width toward the lower surface of the bump part and a second slope different from the first slope. The first slope and the second slope can be provided by a flattening process or a pretreatment process of the bump part. For example, the bump part can include a plurality of first bumps and second bumps, and each of the first and second bumps can have a first slope and a second slope. Through this, the embodiment can allow the bump parts to have a uniform height, thereby minimizing the height deviation therebetween. Furthermore, the embodiment can allow the bump parts including a plurality of bumps to have a same height. Through this, the embodiment can allow a semiconductor device to be stably disposed on a bump part, thereby allowing the semiconductor device to operate smoothly. Therefore, the embodiment can improve the operating characteristics of the semiconductor package and an electronic product including the same.

In addition, the first slope of the bump part can be covered by the third insulating layer or an upper metal layer. The embodiment can make the first slope of the bump part come into contact with the third insulating layer or the upper metal layer, thereby increasing a contact area therebetween. Through this, the embodiment can increase the bonding strength of the bump part and the third insulating layer or the upper metal layer, and can solve the problem of them being separated from each other. Through this, the embodiment can improve the mechanical reliability and/or electrical reliability of the circuit board and the semiconductor package including the same.

In addition, the first slope of the bump part can include a portion that overlaps the first or second insulating layer and does not contact the first or second insulating layer. In addition, at least a part of the first slope can be covered by the upper metal layer or the third insulating layer. Through this, the embodiment can prevent a bonding member such as solder from spreading into the bump part. In addition, the embodiment can allow an intermetallic compound formed by the connecting member to be provided far from the first wiring electrode, and through this, can solve the problem of cracking or deterioration of electrical characteristics of the bump part that may be caused by the intermetallic compound.

In addition, the embodiment can improve the signal transmission characteristics of the circuit board and the semiconductor package accordingly by making the bump parts have a uniform height. For example, the embodiment can minimize signal transmission loss caused by a height difference of a bump part. Furthermore, the embodiment can prevent a change in impedance characteristics that changes due to a height difference. Through this, the embodiment can further improve the mechanical reliability and physical reliability of a semiconductor package and an electronic product including the same.

### DESCRIPTION OF DRAWINGS

FIG. 1a is a cross-sectional view showing a semiconductor package according to a first embodiment.

FIG. 1b is a cross-sectional view showing a semiconductor package according to a second embodiment.

FIG. 1c is a cross-sectional view showing a semiconductor package according to a third embodiment.

FIG. 1d is a cross-sectional view showing a semiconductor package according to a fourth embodiment.

FIG. 1e is a cross-sectional view showing a semiconductor package according to a fifth embodiment.

FIG. 2a is a cross-sectional view showing a circuit board according to a first embodiment.

FIG. 2b is a drawing showing a modified example of the circuit board of FIG. 2a.

FIG. 3 is an enlarged view showing a region R1 of FIG. 2a.

FIG. 4 is an enlarged view showing a region R1 of a circuit board according to a second embodiment.

FIG. 5 is an enlarged view showing a region R1 of a circuit board according to a third embodiment.

FIG. 6 is an enlarged view showing a region R1 of a circuit board according to a fourth embodiment.

FIG. 7 is an enlarged view showing a region R1 of a circuit board according to a fifth embodiment.

FIG. 8 is an enlarged view showing a region R1 of a circuit board according to a sixth embodiment.

FIGS. 9 to 23 are drawings showing a manufacturing method of the circuit board shown in FIG. 2a in order of processes.

### Best Mode

Hereinafter, exemplary embodiments of the present invention will be described in detail with reference to the accompanying drawings, wherein like reference numerals are used to designate identical or similar elements, and redundant description thereof will be omitted. The suffix “module” and “portion” of the components used in the following description are only given or mixed in consideration of ease of preparation of the description, and there is no meaning or role to be distinguished as it is from one another. Also, in the following description of the embodiments of the present invention, a detailed description of related arts will be omitted when it is determined that the gist of the embodiments disclosed herein may be obscured. Also, the accompanying drawings are included to provide a further understanding of the invention, are incorporated in, and constitute a part of this description, and it should be understood that the invention is intended to cover all modifications, equivalents, or alternatives falling within the spirit and scope of the invention.

Terms including ordinals, such as first, second, etc., may be used to describe various components, but the elements are not limited to these terms. The terms are used only for distinguishing one component from another.

When a component is referred to as being “connected” or “contacted” to another component, it may be directly connected or joined to the other component, but it should be understood that other component may be present therebetween. When a component is referred to as being “directly connected” or “directly contacted” to another component, it should be understood that other component may not be present therebetween.

A singular representation includes plural representations, unless the context clearly implies otherwise.

In the present application, terms such as “including” or “having” are used to specify the presence of features, numbers, steps, operations, components, parts, or combinations thereof described in the description. However, it should be understood that the terms do not preclude the presence or addition of one or more other features, numbers, steps, operations, components, parts, or combinations thereof.

Hereinafter, embodiments of a present invention will be described in detail with reference to attached drawings.

### Electronic Device

Before describing the embodiment, an electronic device to which the semiconductor package of the embodiment is applied will be briefly described. The electronic device includes a main board (not shown). The main board may be physically and/or electrically connected to various components. For example, the main board may be connected to the semiconductor package of the embodiment. Various semiconductor devices may be mounted on the semiconductor package.

The semiconductor device may include an active device and/or a passive device. The active device may be a semiconductor chip in the form of an integrated circuit (IC) in which hundreds to millions of devices are integrated in one semiconductor device. The semiconductor device may be a logic chip, a memory chip, or the like. The logic chip may be a central processor (CPU), a graphics processor (GPU), or the like. For example, the logic chip may be an application processor (AP) chip including at least one of a central processor (CPU), a graphics processor (GPU), a digital signal processor, a cryptographic processor, a microprocessor and a microcontroller, or an analog-digital converter, an application-specific IC (ASIC), or the like, or a chip set comprising a specific combination of those listed so far.

The memory chip may be a stack memory such as HBM. The memory chip may also include a memory chip such as volatile memory (e.g., DRAM), non-volatile memory (e.g., ROM), flash memory, and the like.

On the other hand, a product group to which the semiconductor package of the embodiment is applied may be any one of CSP (Chip Scale Package), FC-CSP (Flip Chip-Chip Scale Package), FC-BGA (Flip Chip Ball Grid Array), POP (Package on Package) and SIP (System in Package), but is not limited thereto.

In addition, the electronic device may be a smart phone, a personal digital assistant, a digital video camera, a digital still camera, a vehicle, a high-performance server, a network system, computer, monitor, tablet, laptop, netbook, television, video game, smart watch, automotive, or the like. However, the embodiment is not limited thereto, and may be any other electronic device that processes data in addition to these.

Hereinafter, a semiconductor package including a circuit board according to an embodiment will be described. The semiconductor package of the embodiment may have various package structures including a circuit board to be described later.

In addition, the circuit board in one embodiment may be a first circuit board described below.

Alternatively, the circuit board in another embodiment may be a second circuit board described below.

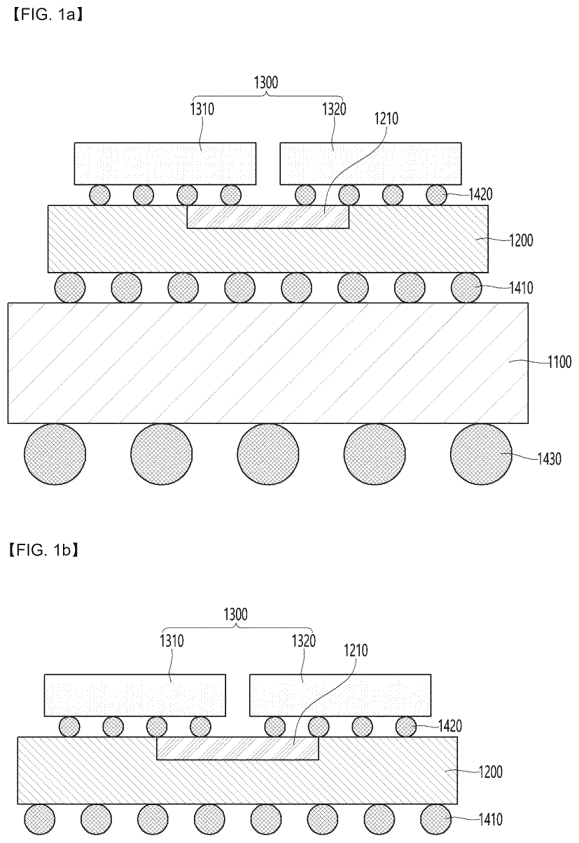

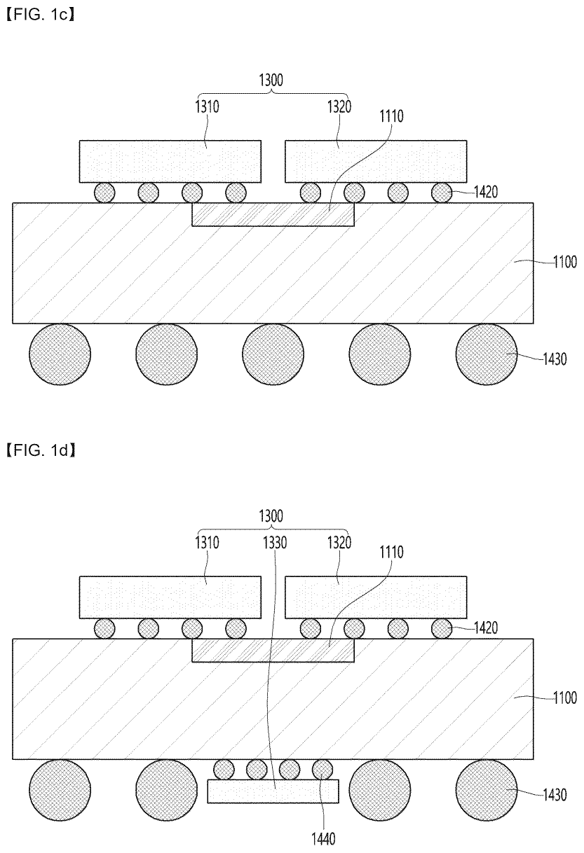

FIG. 1a is a cross-sectional view showing a semiconductor package according to a first embodiment, FIG. 1b is a cross-sectional view showing a semiconductor package according to a second embodiment, FIG. 1c is a cross-sectional view showing a semiconductor package according to a third embodiment, FIG. 1d is a cross-sectional view showing a semiconductor package according to a fourth embodiment, and FIG. 1e is a cross-sectional view showing a semiconductor package according to a fifth embodiment.

Referring to FIG. 1a, the semiconductor package according to the first embodiment includes a first circuit board 1100, a second circuit board 1200, and a semiconductor device 1300.

The first circuit board 1100 may mean a package circuit board.

For example, the first circuit board 1100 may provide a space to which at least one external circuit board is coupled. The external circuit board may refer to a second circuit board 1200 coupled to the first circuit board 1100. Also, the external circuit board may refer to a main board included in an electronic device coupled to a lower portion of the first circuit board 1100.

Also, although not shown in the drawing, the first circuit board 1100 may provide a space in which at least one semiconductor device is mounted.

The first circuit board 1100 may include at least one insulating layer, an electrode part disposed on the at least one insulating layer.

A second circuit board 1200 may be disposed on the first circuit board 1100.

The second circuit board 1200 may be an interposer. For example, the second circuit board 1200 may provide a space in which at least one semiconductor device is mounted. The second circuit board 1200 may be connected to the at least one semiconductor device 1300. For example, the second circuit board 1200 may provide a space in which the first semiconductor device 1310 and the second semiconductor device 1320 are mounted. The second circuit board 1200 may electrically connect the first and second semiconductor devices 1310 and 1320 and the first circuit board 1100 while electrically connecting the first semiconductor device 1310 and the second semiconductor device 1320. That is, the second circuit board 1200 may perform a horizontal connection function between a plurality of semiconductor devices and a vertical connection function between the semiconductor devices and the package circuit board.

FIG. 1a illustrates that the first and second semiconductor devices 1310 and 1320 are disposed on the second circuit board 1200, but is not limited thereto. For example, one semiconductor device may be disposed on the second circuit board 1200, or alternatively, three or more semiconductor devices may be disposed. In addition, although FIG. 1a illustrates a structure in which two semiconductor devices 1310 and 1320 are horizontally connected, a structure in which three or more semiconductor devices are horizontally connected may be provided.

The second circuit board 1200 may be disposed between at least one semiconductor device 1300 and the first circuit board 1100.

In an embodiment, the second circuit board 1200 may be an active interposer. The second circuit board 1200 according to an embodiment may have a structure that is vertically stacked on the first circuit board 1100 and may have functions of multiple logic chips. Having the function of a logic chip may mean that it may have functions of an active device and a passive device. In addition, the active interposer may perform a function of a corresponding logic chip while performing a signal transmission function between a second logic chip disposed thereon and the first circuit board 1100 and a function to horizontally connect electrical signals between semiconductor devices 1300.

According to another embodiment, the second circuit board 1200 may be a passive interposer. For example, the second circuit board 1200 may function as a signal relay between the semiconductor device 1300 and the first circuit board 1100, and can have a passive device function such as a resistor, capacitor, or inductor. For example, a number of terminals of the semiconductor device 1300 is gradually increasing due to 5G, Internet of Things (IOT), increased image quality, and increased communication speed. That is, the number of terminals provided in the semiconductor device 1300 increases, thereby reducing the width of the terminals or an interval between the plurality of terminals. In this case, the first circuit board 1100 may be connected to the main board of the electronic device. There is a problem in that the thickness of the first circuit board 1100 increases or the layer structure of the first circuit board 1100 becomes complicated in order for the electrodes provided on the first circuit board 1100 to have a width and an interval to be respectively connected to the semiconductor device 1300 and the main board. Accordingly, in the first embodiment, the second circuit board 1200 may be disposed on the first circuit board 1100 and the semiconductor device 1300. In addition, the second circuit board 1200 may include electrodes having a fine width and an interval corresponding to the terminals of the semiconductor device 1300.

The semiconductor device 1300 may be an application processor (AP) chip including at least one of a central processor (CPU), a graphics processor (GPU), a digital signal processor, a cryptographic processor, a microprocessor and a microcontroller, or an analog-digital converter, an application-specific IC (ASIC), or the like, or a chip set comprising a specific combination of those listed so far. The memory chip may be a stack memory such as HBM. The memory chip may also include a memory chip such as volatile memory (e.g., DRAM), non-volatile memory (e.g., ROM), flash memory, and the like.

Meanwhile, the semiconductor package of the first embodiment includes a bonding part.

For example, the semiconductor package includes a first bonding part 1410 disposed between the first circuit board 1100 and the second circuit board 1200. The first bonding part 1410 may electrically connect the second circuit board 1200 to the first circuit board 1100 while coupling them.

For example, the semiconductor package may include the second bonding part 1420 disposed between the second circuit board 1200 and the semiconductor device 1300. The second bonding part 1420 electrically connects the semiconductor device 1300 to the second circuit board 1200 while coupling them.

The semiconductor package may include a third bonding part 1430 disposed on a lower surface of the first circuit board 1100. The third bonding part 1430 may electrically connect the first circuit board 1100 to the main board while coupling them.

At this time, the first bonding part 1410, the second bonding part 1420, and the third bonding part 1430 may electrically connect between the plurality of components by using at least one bonding method of wire bonding, solder bonding and metal-to-metal direct bonding. That is, since the first bonding part 1410, the second bonding part 1420, and the third bonding part 1430 have a function of electrically connecting a plurality of components, when the metal-to-metal direct bonding is used, the bonding part of the semiconductor package may be understood as an electrically connected portion, not a solder or wire.

The wire bonding method may refer to electrically connecting a plurality of components using a conductive wire such as gold (Au). Also, the solder bonding method may electrically connect a plurality of components using a material containing at least one of Sn, Ag, and Cu. In addition, the metal-to-metal direct bonding method may refer to recrystallization by applying heat and pressure between a plurality of components without the presence of solder, wire, conductive adhesive, etc. In addition, to directly bond between the plurality of components. In addition, the metal-to-metal direct bonding method may refer to a bonding method by the second bonding part 1420. In this case, the second bonding part 1420 may mean a metal layer formed between a plurality of components by the recrystallization.

Specifically, the first bonding part 1410, the second bonding part 1420, and the third bonding part 1430 may couple a plurality of components to each other by a thermal compression (TC) bonding method. The thermal compression bonding may refer to a method of directly coupling a plurality of components by applying heat and pressure to the first bonding part 1410, the second bonding part 1420, and the third bonding part 1430.

At this time, at least one of the first circuit board 1100 and the second circuit board 1200 may be provided with a protrusion that protrudes outwardly away from the insulating layer of the corresponding board, on which the first bonding part 1410, the second bonding part 1420, and the third bonding part 1430 are disposed. The protrusion may protrude outwardly from the first circuit board 1100 or the second circuit board 1200.

The protrusion may be referred to as a bump, a post, or a pillar. Preferably, the protrusion may refer to an electrode on which a second bonding part 1420 for coupling with the semiconductor device 1300 is disposed among the electrodes of the second circuit board 1200. That is, as the pitch of the terminals of the semiconductor device 1300 becomes finer, a short circuit may occur between the plurality of second bonding parts 1420 that are respectively connected to the plurality of terminals of the semiconductor device 1300 by a conductive adhesive such as a solder. Therefore, the embodiment may perform thermal compression bonding to reduce a volume of the second bonding part 1420 and prevent short circuits between conductive adhesives such as solder. In addition, in order to secure diffusion prevention and alignment to prevent an intermetallic compound (IMC) formed between a conductive adhesive such as solder and a protrusion from diffusing into the interposer and/or the circuit board, a protrusion may be included in the electrode of the second circuit board 1200 on which the second bonding part 1420 is disposed.

In addition, the semiconductor package may include a connection member 1210.

The connection member may be referred to as a bridge circuit board. For example, the connection member 1210 may include a redistribution layer. The connection member 1210 may perform a function of electrically connecting a plurality of semiconductor devices horizontally to each other. An integration level of devices such as transistors integrated into semiconductor devices is increasing, but due to difficulties in semiconductor processes and issues such as yield, functionally separated chip-let units of semiconductor devices may have a signal connection function, or may have a signal connection function for devices with different functions such as CPUs and GPUS, or GPUs and HBMs. In addition, since the semiconductor package and the semiconductor device have a large difference in a width or spacing of the circuit pattern, etc., a buffering role of the circuit pattern for electrical connection is required. Here, the buffering role may mean having a size between a width or spacing of the circuit pattern of the semiconductor package and a width or spacing of the circuit pattern of the semiconductor device, and the redistribution layer may include a function of performing the buffering role.

In one embodiment, the connection member 1210 may be an inorganic bridge. As an example, the inorganic bridge may include a silicon bridge. That is, the connection member 1210 may include a silicon circuit board and a redistribution layer disposed on the silicon circuit board.

In another embodiment, the connection member 1210 may be an organic material bridge. For example, the connection member 1210 may include an organic material. For example, the connection member 1210 may include an organic circuit board including an organic material instead of the silicon circuit board.

The connection member 1210 may be embedded in the second circuit board 1200.

For this purpose, the second circuit board 1200 may include a cavity, and the connection member 1210 may be disposed in the cavity of the second circuit board 1200. The connection member 1210 may horizontally connect a plurality of semiconductor devices disposed on the second circuit board 1200.

Referring to FIG. 1b, the semiconductor package according to the second embodiment may include a second circuit board 1200 and a semiconductor device 1300. In this case, the semiconductor package of the second embodiment may have a structure in which the first circuit board 1100 is removed compared to the semiconductor package of the first embodiment.

That is, the second circuit board 1200 of the second embodiment may function as a package circuit board while performing an interposer function.

The first bonding part 1410 disposed on the lower surface of the second circuit board 1200 may couple the second circuit board 1200 to the main board of the electronic device.

Referring to FIG. 1c, the semiconductor package according to the third embodiment may include a first circuit board 1100 and a semiconductor device 1300.

In this case, the semiconductor package of the third embodiment may have a structure in which the second circuit board 1200 is omitted compared to the semiconductor package of the first embodiment.

That is, the first circuit board 1100 of the third embodiment can function as a package circuit board while also performing the function of connecting the semiconductor device 1300 and a main board. To this end, the first circuit board 1100 may include a connection member 1110 for connecting the plurality of semiconductor devices. The connection member 1110 may be an inorganic bridge or an organic material bridge connecting a plurality of semiconductor devices.

Referring to FIG. 1d, the semiconductor package of the fourth embodiment further may include a third semiconductor device 1330 compared to the semiconductor package of the third embodiment.

To this end, a fourth bonding part 1440 may be disposed on the lower surface of the first circuit board 1100.

A third semiconductor device 1330 may be disposed on the fourth bonding part 1400. That is, the semiconductor package of the fourth embodiment may have a structure in which semiconductor devices are mounted on upper and lower sides, respectively.

In this case, the third semiconductor device 1330 may have a structure disposed on the lower surface of the second circuit board 1200 in the semiconductor package of FIG. 1b.

Referring to FIG. 1e, the semiconductor package according to a sixth embodiment includes a first circuit board 1100. A first semiconductor device 1310 and a second semiconductor device 1320 are disposed on the first circuit board 1100. To this end, a first bonding part 1410 is disposed between the first circuit board 1100 and the first semiconductor device 1310 the second semiconductor device 1320. When the first bonding part 1410 is provided with a fine pattern, as described above, in order to perform thermal compression bonding, the first bonding part 1410 may include a protrusion that protrudes from the first circuit board 1100 toward the first and second semiconductor devices 1310 and 1320.

A connection member 1110 can be embedded in the first circuit board 1110. The connection member 1110 can horizontally connect the first and second semiconductor devices 1310 and 1320.

In addition, the first circuit board 1100 includes a conductive coupling portion 1450. The conductive coupling portion 1450 protrudes further than the first bonding part 1410 toward the second semiconductor device 1320 from the first circuit board 1100. In the case where the first bonding part 1410 includes a protrusion, the conductive coupling portion 1450 is provided to protrude further than the protrusion toward the first and second semiconductor devices.

According to an embodiment, a third semiconductor device 1330 is disposed on the conductive coupling portion 1450. At this time, the third semiconductor device 1330 may mean an active interposer or a passive interposer. The third semiconductor device 1330 is connected to the first circuit board 1100 through the conductive coupling portion 1450. In addition, a second bonding part 1420 is disposed between the first and second semiconductor devices 1310 and 1320 and the third semiconductor device 1330.

Accordingly, the third semiconductor device 1330 is electrically connected to the first semiconductor device 1310 through the second bonding part 1420.

That is, the third semiconductor device 1330 is connected to the first circuit board 1100 through the conductive coupling portion 1450, and may be also connected to the first and second semiconductor devices 1310 and 1320 through the second bonding part 1420.

In this case, the third semiconductor device 1330 may receive a power signal and/or electric power through the conductive coupling portion 1450. In addition, the third semiconductor device 1330 can exchange communication signals with the first and second semiconductor devices 1310 and 1320 through the second bonding part 1420 or can horizontally electrically connect the first and second semiconductor devices 1310 and 1320.

The semiconductor package of the fifth embodiment may have a function of supplying a power signal and/or power to the third semiconductor device 1330 through the conductive coupling portion 1450, thereby providing sufficient power for driving the third semiconductor device 1330, smoothly controlling power operation, and reducing interference between signals when connecting signals of the first to third semiconductor devices 1310, 1320 to suppress noise.

Meanwhile, if the fifth embodiment is modified, the third semiconductor device 1330 may have a structure disposed on a package circuit board. In this case, a semiconductor package including the third semiconductor device 1330 is provided in a POP (Package On Package) structure disposed on the first circuit board 1100. For example, the third semiconductor device 1330 may be a memory package including a memory chip. In addition, the memory package may be coupled on the conductive coupling portion 1450. At this time, the memory package may not be directly connected to the first and second semiconductor devices 1310, 1320. Here, not being directly connected means not being connected through the second bonding part 1420. That is, the third semiconductor device 1330 is connected to the first and second semiconductor devices 1310, 1320 through a wiring included in the first circuit board 1100.

Hereinafter, a circuit board of an embodiment will be described. The circuit board described below may be one of the first circuit board 1100 and the second circuit board 1200 of the semiconductor package.

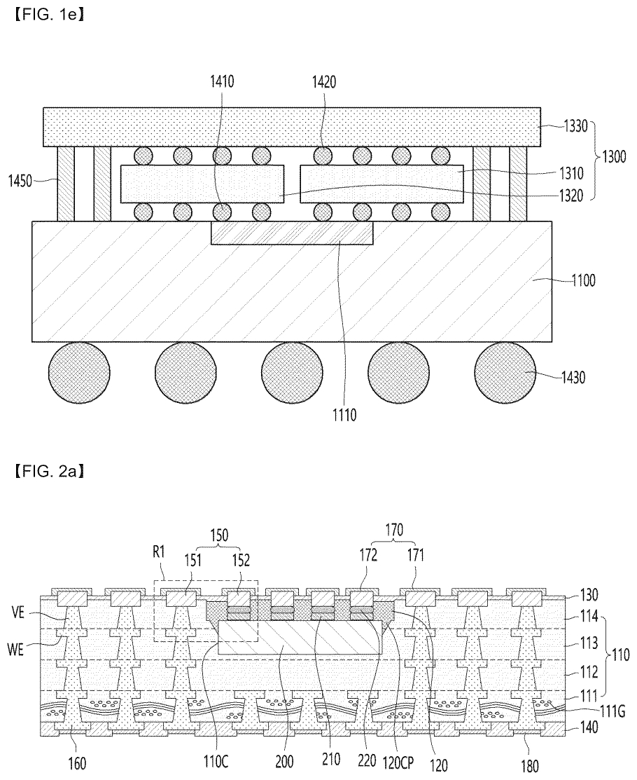

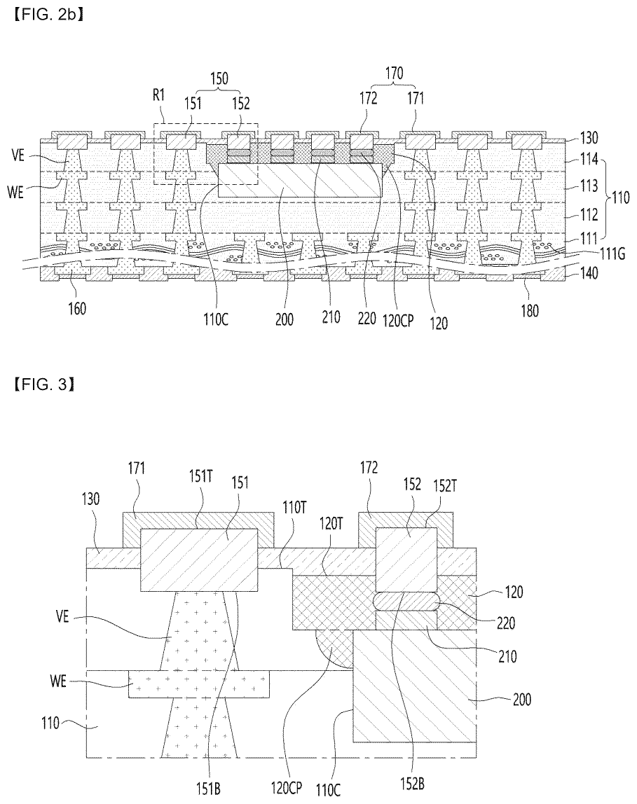

FIG. 2a is a cross-sectional view showing a circuit board according to a first embodiment, FIG. 2b is a drawing showing a modified example of the circuit board of FIG. 2a, and FIG. 3 is an enlarged view showing a region R1 of FIG. 2a.

Hereinafter, a circuit board of an embodiment will be described in detail with reference to FIGS. 2a, 2b, and 3.

Referring to FIGS. 2a, 2b, and 3, the circuit board includes a circuit board and a connection member 200 embedded in the circuit board. The connection member 200 is disposed in the circuit board and can horizontally connect a plurality of semiconductor devices mounted on the circuit board through this.

For this purpose, the connection member 200 may be provided with high-density electrode patterns. In addition, the connection member 200 may include at least one of an inorganic bridge and an organic bridge.

The connection member 200 is provided with a pad part 210. The pad part 210 may mean an electrode pattern disposed on an uppermost side of the connection member 200. A bonding part 220 is provided on the pad part 210 of the connection member 200. The bonding part 220 may be a solder, but is not limited thereto. The bonding part 220 allows the pad part 210 of the connection member 200 to be coupled to a second bump 152 of a bump part 150 to be described later. Although not shown in the drawing, the pad part 210 of the connection member 200 may include a protrusion. If the protrusion is included, the bonding part 220 may not be necessary. Accordingly, the protrusion of the connection member 200 may be provided to protrude from an upper surface of the circuit board, and may be provided as a structure integrated with the second bump 152.

Meanwhile, the circuit board provides a space in which the connection member 200 is embedded. In addition, the circuit board may provide a space in which a plurality of semiconductor devices are mounted. For example, a first semiconductor device including a first terminal and a second semiconductor device including a second terminal are mounted on the circuit board, which are spaced apart from each other in a horizontal direction. At least one first terminal provided on the first semiconductor device and at least one second terminal provided on the second semiconductor device are electrically connected to each other through the connection member 200. Therefore, terminals for mutual signal exchange are electrically connected to the connection member 200.

The circuit board includes a first insulating layer 110.

The first insulating layer 110 may include an organic material that does not include a reinforcing member, which enables excellent processability, slimming of the circuit board, and miniaturization of the electrode part of the circuit board. For example, the first insulating layer 110 of the circuit board can use ABF (Ajinomoto Build-up Film), a product released by Ajinomoto Co., Ltd., as an example, and can use FR-4, BT (Bismaleimide Triazine), PID (Photo Imageable Dielectric resin), BT, etc.

The first insulating layer 110 can be provided in multiple layers. The first insulating layer 110 can be provided in an inner layer of the circuit board. Being provided in the inner layer can mean that another insulating layer can be disposed on at least one of upper and lower layers of the first insulating layer 110.

For example, the first insulating layer 110 can include a first layer 111, a second layer 112, a third layer 113, and a fourth layer 114, but the embodiment is not limited thereto.

In one embodiment, the first layer 111, the second layer 112, the third layer 113, and the fourth layer 114 of the first insulating layer 110 may each be formed of a same insulating material, but the embodiment is not limited thereto, and at least one layer may be formed of a different insulating material from the other layers.

In another embodiment, at least one of the first layer 111, the second layer 112, the third layer 113, and the fourth layer 114 of the first insulating layer 110 may include an insulating material different from at least one other layer.

When the first layer 111, the second layer 112, the third layer 113, and the fourth layer 114 of the first insulating layer 110 are formed of a same material, an interface between each layer may not be easily distinguished. In this case, the distinction between the layers may be made by an electrode part disposed in the first insulating layer 110.

For example, the electrode part includes a wiring electrode WE provided at an interface between the first layer 111, the second layer 112, the third layer 113, and the fourth layer 114 of the first insulating layer 110, respectively. In addition, the electrode part includes a via electrode VE provided between the wiring electrodes WE disposed in different layers. A width of the wiring electrode WE in a horizontal direction is different from a width of the via electrode VE in the horizontal direction. Therefore, the interlayer distinction can be made by utilizing the difference between the width of the wiring electrode WE and the width of the via electrode VE. In addition, a slope of a side surface of the wiring electrode WE can be different from a slope of a side surface of the via electrode VE. Therefore, the interlayer distinction can be made by utilizing the difference between the slope of the side surface of the wiring electrode WE and the slope of the side surface of the via electrode VE.

Meanwhile, even if the first layer 111, the second layer 112, the third layer 113, and the fourth layer 114 of the first insulating layer 110 include a same insulating material, the interface between them can be distinguished.

Through the laminated structure of the first insulating layer 110 described above, the circuit board of the embodiment can efficiently electrically connect at least one semiconductor device and/or the second circuit board to the main board.

Meanwhile, at least one of the first layer 111, the second layer 112, the third layer 113, and the fourth layer 114 of the first insulating layer 110 in one embodiment can include a reinforcing member 110G. In one embodiment, the reinforcing member 110G can mean glass fiber. In another embodiment, the reinforcing member 110G can mean GCP (Glass Core Primer). When the reinforcing member 100G means glass fiber, at least one layer among the first to fourth layers 111, 112, 113, and 114 of the first insulating layer 110 is provided as a core layer.

The reinforcing member 110G is distinguished from a filler. For example, the reinforcing member 110G may include a reinforcing material extending along the horizontal direction within the first insulating layer 110, which has a different meaning from an inorganic filler that is spaced apart from each other. For example, a length or a width of the reinforcing member 110G in the horizontal direction is different from a length or a width of the filler in the horizontal direction. For example, the reinforcing member 110G may be disposed in a curved shape within the first insulating layer 110, and accordingly, the width of the reinforcing member 110G in the horizontal direction may be larger than the width of the first insulating layer 110 in the horizontal direction.

In the embodiment, a rigidity of the circuit board can be improved by including at least one of the first layer 111, the second layer 112, the third layer 113, and the fourth layer 114 of the first insulating layer 110 including a reinforcing member 110G. For example, the reinforcing member 110G can have a function of preventing the circuit board from being greatly bent in a specific direction. Therefore, the first insulating layer 110 can be prevented from being bent during a manufacturing process of the circuit board, and thereby the positional accuracy of the wiring electrode WE and the via electrode VE can be improved, and further the alignment between them can be improved. In addition, as the rigidity of the circuit board is secured, the semiconductor device can be stably coupled on the circuit board, and thus the operating characteristics of the semiconductor device can be improved. In addition, as the rigidity of the circuit board is secured, the connection member 200 can be stably embedded in the circuit board. Accordingly, the embodiment can stably support the connection member 200, thereby minimizing the thermal stress transmitted to the connection member 200. Therefore, the embodiment can improve the signal transmission characteristics through the connection member 200. Furthermore, the electronic product and/or server to which the semiconductor package of the embodiment is applied can operate stably, thereby improving product reliability.

Meanwhile, when the reinforcing member 110G is included in at least one of the first layer 111, the second layer 112, the third layer 113, and the fourth layer 114 of the first insulating layer 110, the reinforcing member 110G is positioned adjacent to a lower surface of the first insulating layer 110. For example, the reinforcing member 110G can be provided in the fourth layer 114 adjacent to the lower surface of the first insulating layer 110. For example, a vertical distance from an upper surface of the first insulating layer 110 to an uppermost end of the reinforcing member 110G may be greater than a vertical distance from a lower surface of the first insulating layer 110 to a lowermost end of the reinforcing member 110G. A semiconductor device may be electrically coupled on the first layer 111 of the first insulating layer 110. The width and spacing of the wiring electrode disposed on the first layer 111 of the first insulating layer 110 may be required to be miniaturized due to miniaturization of the width and spacing of the terminal of the semiconductor device. In contrast, the wiring electrode disposed under the fourth layer 114 of the first insulating layer 110 may be connected to an external circuit board (e.g., a package circuit board or a main board) and thus may have a relatively large width and spacing. At this time, the wiring electrode disposed on the insulating layer provided with the reinforcing member 100G may be difficult to be miniaturized due to manufacturing process restrictions caused by the reinforcing member. Accordingly, the embodiment can arrange the reinforcing member 110G in the fourth layer 114 adjacent to the lower surface of the first insulating layer 110, thereby improving the rigidity of the circuit board while enabling miniaturization of the wiring electrode disposed on the first layer 111, the second layer 112, and the third layer 113 of the first insulating layer 110. Through this, the connection member 200 disposed in the first insulating layer 110 may not overlap with the reinforcing member 110G in the horizontal direction.

Meanwhile, in FIG. 2a, a layer including the reinforcing member 110G is illustrated as being disposed on a lowermost side of the first insulating layer 110, but the embodiment is not limited thereto. For example, referring to FIG. 2b, a layer including the reinforcing member 110G may be disposed in a center of a stacked structure in a thickness direction of the first insulating layer 110. At this time, based on the layer including the reinforcing member 110G, layers not including the reinforcing member may be provided on the upper and lower portions of the layer including the reinforcing member, respectively.

For example, the first insulating layer 110 may include a layer including the reinforcing member 110G, and a plurality of layers having mutually symmetrical numbers of layers and not including the reinforcing member 110G may be laminated on the upper and lower portions of the layer including the reinforcing member 110G.

Meanwhile, the first insulating layer 110 includes a cavity 110C. The cavity 110C provides a space in which the connection member 200 is disposed. According to one embodiment, the cavity 110C may include a region having a same width as a width of the connection member 200. That is, at least a portion of an inner wall of the cavity 110C may be in contact with a side surface of the connection member 200. Through this, the connection member 200 can be disposed in the cavity 110C of the first insulating layer 110 and a position of the connection member 200 can be fixed through the first insulating layer 110. Therefore, the embodiment can prevent the connection member 200 from being bent due to thermal stress, and thus improve the physical reliability and mechanical reliability of the circuit board.

The second insulating layer 120 is disposed on the connection member 200. The second insulating layer 120 covers an upper region of the connection member 200. The second insulating layer 120 is provided in the cavity 100C of the first insulating layer 110. The inner wall of the cavity 100C has a step. For example, a part of the inner wall of the cavity 100C is in contact with the second insulating layer 120. In addition, another part of the inner wall of the cavity 100C is in contact with the connection member 200. The inner wall of the cavity 100C in contact with the second insulating layer 120 and the inner wall of the cavity 100C in contact with the connection member 200 have a step. For example, the width of the cavity 100C changes in a direction from the upper surface of the first insulating layer 110 toward the lower surface of the first insulating layer 110. In addition, the width of the cavity 100C in the horizontal direction at the inner wall in contact with the second insulating layer 120 is different from the width of the cavity 100C in the horizontal direction at the inner wall in contact with the connection member 200. Preferably, the width of the cavity 100C in the horizontal direction at the inner wall in contact with the second insulating layer 120 is larger than the width of the cavity 100C in the horizontal direction at the inner wall in contact with the connection member 200.

According to one embodiment, the second insulating layer 120 includes an insulating material different from that of the first insulating layer 110. The second insulating layer 120 has properties different from those of the first insulating layer 110. For example, a coefficient of thermal expansion of the second insulating layer 120 may be different from that of the first insulating layer 110. For example, a stiffness of the second insulating layer 120 may be different from that of the first insulating layer 110. Preferably, the stiffness of the second insulating layer 120 may be smaller than that of the first insulating layer 110. Accordingly, the embodiment can alleviate thermal stress and other stresses applied to the connection member 200. In addition, when the connection member 200 is provided as an organic bridge, the embodiment can alleviate damage such as cracks in the semiconductor package caused by a difference in coefficient of thermal expansions between the organic bridge and the first insulating layer 110.

For example, the second insulating layer 120 may be NCP (Non Conductive paste). However, the embodiment is not limited thereto, and the second insulating layer 120 may include an insulating material that can stably fix the connection member 200 while alleviating thermal stress applied to the semiconductor package, thereby minimizing stress transmitted to the connection member 200.

Specifically, the connection member 200 disposed in the cavity 110C of the first insulating layer 110 overlaps the second insulating layer 120 in the vertical direction. Through this, the embodiment can prevent the stress in the first insulating layer 110 from being transferred to the connection member 200. The second insulating layer 120 can serve as a buffer to buffer the stress.

In the case of the embodiment in which the connection member 200 includes the pad part 210 and is connected to the second bump 152 through the bonding part 220, the second insulating layer 120 is provided to surround the pad part 210 of the connection member 200 and the bonding part 220 disposed on the pad part 210. The embodiment can buffer the stress transferred to the second bump 152, the pad part 210, and the bonding part 220 by using the second insulating layer 120. Therefore, the embodiment can prevent cracks from occurring in the bonding part 220 due to stress. Through this, the embodiment can improve the electrical connection reliability between the pad part 210, the bonding part 220, and the second bump 152. Therefore, the embodiment can stably connect a plurality of semiconductor devices by the connection member 200, thereby improving the operation reliability of the plurality of semiconductor devices.

Meanwhile, a width in the horizontal direction of the second insulating layer 120 is larger than a width in the horizontal direction of the connection member 200. The embodiment can maximize the effect of the buffer function through the second insulating layer 120, thereby further improving the physical reliability and electrical reliability of the semiconductor package.

The second insulating layer 120 can include an extension part 120CP. The extension part 120CP of the second insulating layer 120 can extend toward the side surface of the connection member 200. For example, the extension part 120CP of the second insulating layer 120 may cover at least a part of the side surface of the connection member 200. Through this, the embodiment may enable the connection member 200 to be more stably disposed within the cavity 110C and further minimize the stress transmitted to the connection member 200.

According to another embodiment, the connection member 200 may be an organic bridge. When the connection member is provided with an organic bridge, a circuit layer may be equipped with a fine pattern for signal connection between semiconductor devices. Therefore, the connection member 200 may include a PID (Photo Imageable Dielectric) material. According to the present embodiment, the PID material has a larger coefficient of thermal expansion than the first insulating layer 110 or the second insulating layer 120. Therefore, since an expansion rate in the connection member 200 due to heat generated during operation is large, cracks may occur in the connection member 200 or the first insulating layer 110. The second insulating layer 120 can improve the operational reliability of the semiconductor device package by alleviating the difference in coefficient of thermal expansion.

Meanwhile, the second insulating layer 120 can have a step difference with the first insulating layer 110. For example, an upper surface 120T of the second insulating layer 120 can be positioned lower than an upper surface 110T of the first insulating layer 110. Through this, the embodiment can improve a contact area with the third insulating layer 130 disposed on the first insulating layer 110 and the second insulating layer 120, and through this, the problem of the third insulating layer 130 being peeled off from the first insulating layer 110 and/or the second insulating layer 120 can be solved. In addition, the first insulating layer 110 and the second insulating layer 120 may have different coefficients of thermal expansion, and thus at least one may expand or contract more than at least the other. At this time, the embodiment may solve the problem of peeling between the first insulating layer 110 and the second insulating layer 120 caused by expansion or contraction by making the upper surface 120T of the second insulating layer 120 and the upper surface 110T of the first insulating layer 110 have a step, thereby improving the mechanical reliability of the semiconductor package.

Meanwhile, the circuit board may further include a third insulating layer 130 and a fourth insulating layer 140.

The third insulating layer 130 is disposed on the upper surfaces of the first insulating layer 110 and the second insulating layer 120, and the fourth insulating layer 140 is disposed on the lower surface of the first insulating layer 110.

The third insulating layer 130 and the fourth insulating layer 140 may be resist layers.

For example, the third insulating layer 130 may be a first resist layer disposed on an uppermost side of the circuit board. For example, the fourth insulating layer 140 may be a second resist layer disposed on a lowermost side of the circuit board.

In one embodiment, the third insulating layer 130 and the fourth insulating layer 140 may include a same insulating material as the first insulating layer 110. However, the embodiment is not limited thereto, and the third insulating layer 130 and the fourth insulating layer 140 may be solder resist, which is an insulating material different from the first insulating layer 110.

The third insulating layer 130 may have a function of protecting the upper surface 110T of the first insulating layer 110 and the upper surface 120T of the second insulating layer 120. The fourth insulating layer 140 may have a function of protecting the lower surface of the first insulating layer 110. Therefore, the third insulating layer 130 and the fourth insulating layer 140 may be referred to as protective layers.

According to one embodiment, a lower surface of the third insulating layer 130 has a step. For example, the third insulating layer 130 may include a first lower surface contacting the upper surface 110T of the first insulating layer 110 and a second lower surface contacting the upper surface 120T of the second insulating layer 120. The second lower surface of the third insulating layer 130 may be positioned lower than the first lower surface. Through this, the embodiment may increase the contact area between the first insulating layer 110, the second insulating layer 120, and the third insulating layer 130, thereby improving the bonding strength therebetween.

The third insulating layer 130 and the fourth insulating layer 140 may be solder resist layers including organic polymer materials. The third insulating layer 130 and the fourth insulating layer 140 may include epoxy acrylate series resins. For example, the third insulating layer 130 and the fourth insulating layer 140 may include resins, curing agents, photo initiators, pigments, solvents, fillers, additives, acrylic series monomers, etc. However, the embodiment is not limited thereto, and the third insulating layer 130 and the fourth insulating layer 140 may be any one of a photo solder resist layer, a cover-lay, and a polymer material.

The circuit board includes an electrode part.

The electrode part is disposed in the first insulating layer 110 and the second insulating layer 120. In addition, at least a part of the electrode part protrudes above the first insulating layer 110 and the second insulating layer 120.

The electrode part may be divided into a wiring electrode WE and a via electrode VE depending on a position or function. The via electrode VE may be disposed between wiring electrodes WE disposed in different layers, and may electrically connect them along the vertical direction. When the first insulating layer 110 has a four-layer structure, the via electrode VE may include first to fourth via electrodes disposed in each layer of the first insulating layer 110.

The wiring electrode disposed on a uppermost side of the wiring electrode WE of the electrode part may have an ETS (Embedded Trace Substrate) structure.

For example, a concave part may be provided on each of the upper surfaces of the first insulating layer 110 and the second insulating layer 120, and at least a part of the wiring electrode WE may be provided in the concave part. At this time, the ETS structure is advantageous for miniaturization compared to a wiring electrode having a general protruding structure. Accordingly, the embodiment enables a formation of wiring electrodes corresponding to the size and pitch of terminals provided in the semiconductor device. Through this, the embodiment can improve the circuit integration. Furthermore, the embodiment can minimize a transmission distance of a signal transmitted through the semiconductor device, thereby minimizing signal transmission loss.

Meanwhile, the wiring electrode WE includes a bump part 150 disposed at the uppermost side. The bump part 150 can function as a pad connected to the semiconductor device.

In addition, the wiring electrode WE includes a terminal electrode 160 disposed at a lowermost side. The terminal electrode 160 can function as a terminal connected to an external circuit board (e.g., a package circuit board or a main board).

The bump part 150 includes a first bump 151 disposed in a concave part provided on the upper surface of the first insulating layer 110. In addition, the bump part 150 includes a second bump 152 disposed in a concave part provided on the upper surface of the second insulating layer 120.

The first bump 151 and the second bump 152 overlap each other in the horizontal direction. At this time, the first bump 151 and the second bump 152 are disposed on insulating layers provided with different insulating materials. That is, the first bump 151 is disposed on the first insulating layer 110 including the first insulating material. In addition, the second bump 152 is disposed on the second insulating layer 120 including a second insulating material different from the first insulating material.

The first bump 151 does not overlap with the connection member 200 in the vertical direction. In addition, the first bump 151 does not overlap with the second insulating layer 120 in the vertical direction. In addition, the second bump 152 overlaps with the connection member 200 in the vertical direction. In addition, the second bump 152 overlaps with the second insulating layer 120 in the vertical direction.

For example, a width of the first bump 151 in the horizontal direction may be different from the width of the second bump 152 in the horizontal direction. According to an embodiment, when the second bump 152 is disposed on the second insulating layer 120, the thermal stress or stress transmitted to the second bump 152 can be reduced by the second insulating layer 120. Therefore, the width of the second bump 152 in the horizontal direction can be made smaller than the width of the first bump 151 in the horizontal direction. Through this, the embodiment can improve the circuit integration of the second bump 152, and thus reduce a volume of the semiconductor package.

According to an embodiment, a part of the first bump 151 is embedded in the first insulating layer 110, and a part of the second bump 152 is embedded in the second insulating layer 120. That is, an area where the first bump 151 and the first insulating layer 110 come into contact and an area where the second bump 152 and the second insulating layer 120 come into contact are different from each other. Therefore, a heat generated during the operation of the semiconductor device or the stress due to the heat applied from an outside is applied differently to the first bump 151 and the second bump 152. In addition, when the connection member 200 is provided as an organic bridge, considering the coefficient of thermal expansion of the connection member 200, it may be more advantageous for the operation reliability if the width of the first bump 151 in the horizontal direction is larger than the width of the second bump 152 in the horizontal direction.

However, the present invention is not limited thereto, and when the width of the first bump 151 in the horizontal direction is reduced in order to improve the circuit integration of the first bump 151, the width of the first bump 151 in the horizontal direction and the width of the second bump 152 in the horizontal direction may be freely designed to be the same.

The second bump 152 is connected to the connection member 200 including relatively fine electrode patterns. At this time, the second bump 152 may have a width in the horizontal direction smaller than the width in the horizontal direction of the first bump 151, thereby reducing the width in the horizontal direction of the pad part 210 of the connection member 200. Accordingly, the embodiment may reduce the volume of the connection member 200.

Meanwhile, at least a portion of the first bump 151 may be disposed in a concave part provided on the upper surface 110T of the first insulating layer 110, and a remaining portion of the first bump 151 may protrude on the upper surface 110T of the first insulating layer 110. Specifically, the upper surface 151T of the first bump 151 may be positioned higher than the upper surface 110T of the first insulating layer 110, and the lower surface 151B of the first bump 151 may be positioned lower than the upper surface 110T of the first insulating layer 110. By embedding at least a portion of the first bump 151 in the first insulating layer 110, the adhesion between the first bump 151 and the first insulating layer 110 may be improved, thereby solving the problem of the first bump 151 being peeled off from the first insulating layer 110. In addition, the upper surface 151T of the first bump 151 may be positioned higher than the upper surface 110T of the first insulating layer 110, and further, can be positioned higher than the upper surface of the third insulating layer 130. Through this, the embodiment can facilitate a mounting process of the semiconductor device on the first bump 151, and when the first bump 151 and the second bump 152 are provided in multiple pieces, a height deviation of each bump can be reduced, thereby improving the processability of the semiconductor package.

Meanwhile, at least a part of the second bump 152 can be disposed in a concave part provided on the upper surface 120T of the second insulating layer 120, and a remaining part can protrude above the upper surface 120T of the second insulating layer 120. Specifically, the upper surface 152T of the second bump 152 can be positioned higher than the upper surface 120T of the second insulating layer 120, and the lower surface 152B of the second bump 152 can be positioned lower than the upper surface 120T of the second insulating layer 120. By embedding at least a portion of the second bump 152 in the second insulating layer 120, the adhesion between the second bump 152 and the second insulating layer 120 can be improved, thereby solving the problem of the second bump 152 being peeled off from the second insulating layer 120. In addition, the upper surface 152T of the second bump 152 can be positioned higher than the upper surface 120T of the second insulating layer 120, and further, can be positioned higher than the upper surface of the third insulating layer 130. Through this, the embodiment can facilitate the mounting process of the semiconductor device on the second bump 152, and when the first bump 151 and the second bump 152 are provided in multiple pieces, the height deviation of each bump can be reduced, thereby improving the processability of the semiconductor package.

The first bump 151 and the second bump 152 are respectively disposed on the first insulating layer 110 and the second insulating layer 120. Being disposed on the first and second insulating layers 110 and 120 means that at least a part of them protrudes and the other part is buried. In other words, if some parts are buried in different insulating layers, a height difference between the first bump 151 and the second bump 152 may occur. As described below, a height difference between the first and second bumps 151 and 152 can be reduced by arranging each part of the first and second bumps 151 and 152 to protrude and each other part of the first and second bumps 151 and 152 to be buried.

Meanwhile, the first bump 151 and the second bump 152 are positioned on a same plane.

Preferably, the upper surface 151T of the first bump 151 may be positioned on a same plane as the upper surface 152T of the second bump 152. The lower surface 151B of the first bump 151 may be positioned on a same plane as the lower surface 152B of the second bump 152.

That is, the first bump 151 and the second bump 152 may have a same height.

Through this, the embodiment can allow the semiconductor device to be stably coupled on the first bump 151 and the second bump 152. For example, when the first bump 151 and the second bump 152 are not flat and have a height difference, the semiconductor device can be coupled on the first bump 151 and the second bump 152 in a tilted state corresponding to the height difference. Furthermore, when the first bump 151 and the second bump 152 have a height difference, a pad positioned relatively high may be connected to a terminal of the semiconductor device, but a pad positioned relatively low may not be electrically connected to a terminal of the semiconductor device, which may cause a problem. In contrast, the upper surfaces of each of the first bump 151 and the second bump 152 of the embodiment may be flat, and further, may be disposed on a same plane. Through this, the semiconductor device may be stably coupled on the first bump 151 and the second bump 152. Accordingly, the embodiment may enable the semiconductor device to operate smoothly, and further, may enable the electronic product or server to operate smoothly, thereby improving product reliability.

Meanwhile, each of the first bump 151 and the second bump 152 may penetrate the third insulating layer 130, and at least a portion thereof may protrude onto the third insulating layer 130.

Meanwhile, an upper metal layer 170 is disposed on the first bump 151 and the second bump 152. The upper metal layer 170 includes a first upper metal layer 171 disposed on the first bump 151 and a second upper metal layer 172 disposed on the second bump 152.

The first upper metal layer 171 may be provided to surround an upper surface and at least a portion of a side surface of the first bump 151. The first upper metal layer 171 may be a bonding portion on which a conductive adhesive, such as solder, for bonding with a semiconductor device is disposed.

For example, the first upper metal layer 171 may be a bonding portion for bonding with a connection member such as a semiconductor device and/or an interposer. The first upper metal layer 171 may include a different metal from the first bump 151. For example, the first upper metal layer 171 may include a metal material for improving bonding strength between the first bump 151 and the conductive adhesive. In addition, the first upper metal layer 171 may include a metal material for preventing diffusion of an intermetallic compound (IMC) toward the first bump 151 due to the arrangement of the conductive adhesive.

For example, the first upper metal layer 171 may include nickel. In addition, when the first upper metal layer 171 includes nickel, the adhesion between the first bump 151 and the conductive adhesive may be improved, and further, diffusion of the intermetallic compound may be prevented. For example, intermetallic compounds have problems of poor mechanical and electrical reliability. In particular, when the first bump 151 includes copper, mechanical reliability problems such as crack problems and/or electrical characteristic degradation caused by the intermetallic compound and/or electrical reliability problems may be further aggravated. At this time, when the first upper metal layer 171 includes nickel and is formed to surround an exposed surface of the first bump 151, diffusion of a conductive adhesive such as solder can be prevented, thereby preventing the formation of an intermetallic compound, thereby improving the electrical and mechanical reliability of the semiconductor package. Meanwhile, the first upper metal layer 171 may include a metal other than nickel. For example, the first upper metal layer 171 may include gold. For example, the first upper metal layer 171 may include palladium.

Meanwhile, the first upper metal layer 171 may cover an entire upper surface of the first bump 151 and at least a portion of the side surface of the first bump 151. For example, at least a portion of the side surface of the first bump 151 may protrude onto the third insulating layer 130. In addition, the first upper metal layer 171 may cover the protruding side surface of the first bump 151. In addition, at least a portion of the first upper metal layer 171 may be disposed on the third insulating layer 130. Through this, the embodiment may improve the adhesion between the first upper metal layer 171 and the first bump 151, thereby improving the bonding strength therebetween. In addition, the embodiment may further prevent the intermetallic compound from diffusing into a gap between the first bump 151 and the third insulating layer 130.

In addition, the second upper metal layer 172 may be provided to surround the upper surface and at least a portion of the side surface of the second bump 152. The second upper metal layer 172 may be a bonding portion where a conductive adhesive, such as solder, for bonding with a semiconductor device is disposed.

For example, the second upper metal layer 172 may be a bonding portion for bonding with a semiconductor device and/or a connection member, such as an interposer. The second upper metal layer 172 may include a different metal from the second bump 152. For example, the second upper metal layer 172 may include a metal material for improving bonding strength between the second bump 152 and the conductive adhesive. In addition, the second upper metal layer 172 may include a metal material that prevents an intermetallic compound (IMC) from diffusing toward the second bump 152 due to the arrangement of the conductive adhesive. For example, the second upper metal layer 172 may include nickel. In addition, when the second upper metal layer 172 includes nickel, the adhesion between the first bump 151 and the conductive adhesive may be improved, and further, diffusion of an intermetallic compound may be prevented. Meanwhile, the second upper metal layer 172 may include a metal other than nickel. For example, the second upper metal layer 172 may include gold. For example, the second upper metal layer 172 may include palladium.

Meanwhile, the second upper metal layer 172 may cover the entire upper surface of the second bump 152 while covering at least a portion of the side surface of the second bump 152. For example, at least a portion of the side surface of the second bump 152 may protrude onto the third insulating layer 130. In addition, the second upper metal layer 172 may cover the protruding side surface of the second bump 152. In addition, at least a portion of the second upper metal layer 172 may be disposed on the third insulating layer 130. Through this, the embodiment may improve the adhesion between the second upper metal layer 172 and the second bump 152, thereby improving the bonding strength therebetween. In addition, the embodiment may further prevent the intermetallic compound from diffusing into a gap between the second bump 152 and the third insulating layer 130.

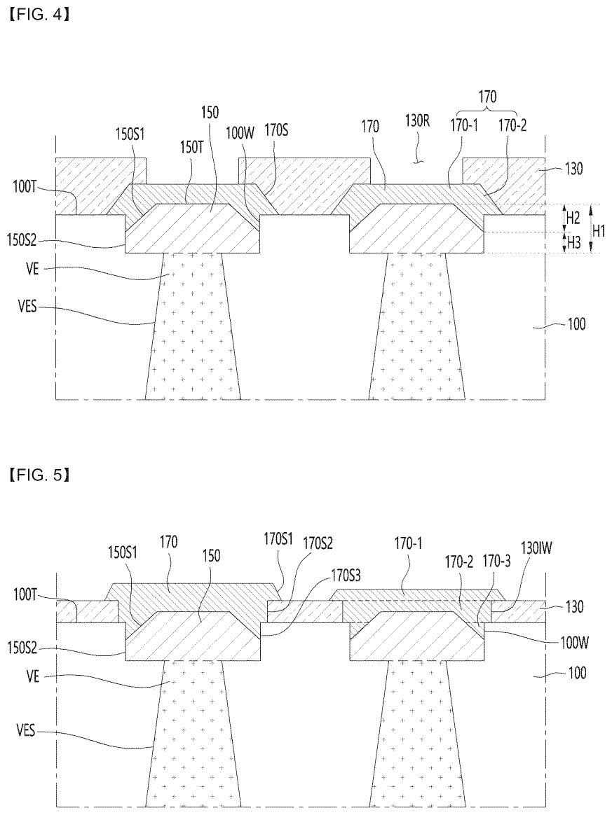

According to FIGS. 4, 5, 6, and 8, the first upper metal layer 171 and the second upper metal layer 172 can contact the first insulating layer 110 and the second insulating layer 120, respectively. Therefore, the adhesive strength between the first upper metal layer 171 and the first insulating layer 110 can be different from the adhesive strength between the second upper metal layer 172 and the second insulating layer 120. In addition, the mechanical and electrical characteristics, such as the heat transfer characteristics, can be different. When the integration degree of the second bump 152 and the integration degree of the first bump 151 are different, the first upper metal layer 171 and the second upper metal layer 172 can be provided to contact different insulating layers in consideration of the mechanical and electrical characteristics, such as the adhesive strength and the heat transfer characteristics.

According to FIG. 7, each of the first upper metal layer 171 and the second upper metal layer 172 can contact a same material. When a density of the first upper metal layer 171 is similar to that of the second upper metal layer 172, the first and second upper metal layers 171 and 172 may be provided with a width smaller than that of the first bump 151 and the second bump 152, respectively.

Meanwhile, a lower metal layer 180 may be disposed on the lower surface of the terminal electrode 160 of the wiring electrode WE. The lower metal layer 180 may include a same metal material as the upper metal layer 170, but is not limited thereto.

Hereinafter, a description will be given of a modified example of the structure of the bump part 150, the third insulating layer 130, and the upper metal layer 170 according to an embodiment.

The bump part 150 described below may be either the first bump 151 or the second bump 152 of FIG. 2a. In one embodiment, the first bump 151 and the second bump 152 may have a same shape and structure. Therefore, the bump part 150 described below may mean either one of the first bump 151 and the second bump 152. In addition, the upper metal layer 170 described below may mean either one of the first and second upper metal layers 171 and 172.

In addition, the insulating layer 100 described below may mean either one of the insulating layer 100 and the second insulating layer 120. For example, when the bump part 150 described below is the first bump 151, the insulating layer 100 may mean a first insulating layer 110. For example, if the bump part 150 described below is a second bump 152, the insulating layer 100 may mean a second insulating layer 120.

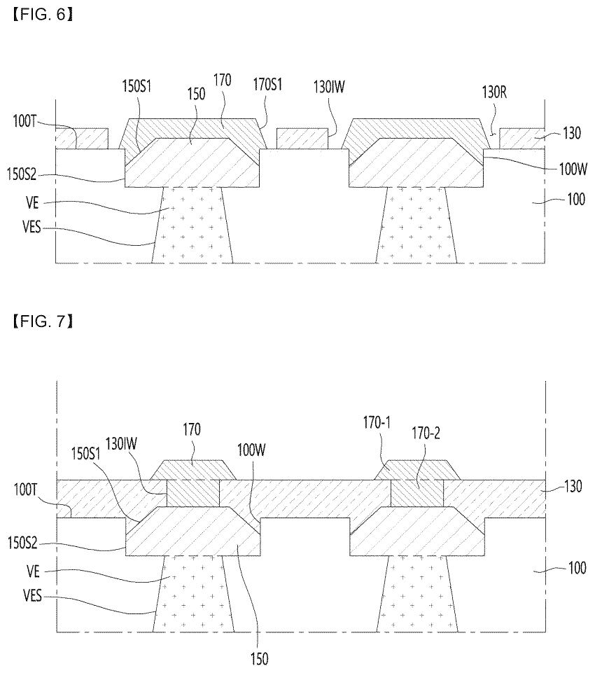

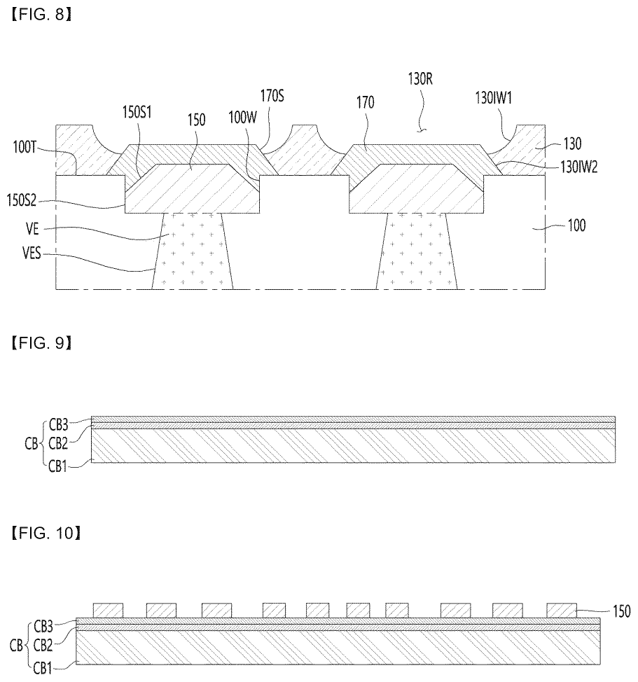

FIG. 4 is an enlarged view showing a region R1 of a circuit board according to a second embodiment, FIG. 5 is an enlarged view showing a region R1 of a circuit board according to a third embodiment, FIG. 6 is an enlarged view showing a region R1 of a circuit board according to a fourth embodiment, FIG. 7 is an enlarged view showing a region R1 of a circuit board according to a fifth embodiment, and FIG. 8 is an enlarged view showing a region R1 of a circuit board according to a sixth embodiment.

Referring to FIG. 4, the bump part 150 may include a tapered slope side with a changing width. The side surface of the bump part 150 may include a portion where the slope changes. Here, the part where the slope changes means not only a direction of the slope changing but also an angle of the slope changing.

For example, the side surface of the bump part 150 may include a first slope 150S1 adjacent to the upper surface 150T of the bump part 150 and having a width that gradually increases toward the lower surface of the bump part 150. In addition, the side surface of the bump part 150 may include a second slope 150S2 adjacent to the lower surface of the bump part 150 and different from the first slope 150S1. The second slope 150S2 may be perpendicular to the upper surface 150T and/or the lower surface of the bump part 150, but is not limited thereto. An internal angle between the upper surface 150T of the bump part 150 and the first slope 150S1 of the bump part 150 may be an obtuse angle. The internal angle between the upper surface 150T of the bump part 150 and the first slope 150S1 may have a range of 95 degrees to 160 degrees. Preferably, the internal angle between the upper surface 150T of the bump part 150 and the first slope 150S1 may have a range of 100 degrees to 150 degrees. More preferably, the internal angle between the upper surface 150T of the bump part 150 and the first slope 150S1 may have a range of 105 degrees to 140 degrees.

If the internal angle between the upper surface 150T of the bump part 150 and the first slope 150S1 is less than 95 degrees, an effect of increasing a contact area between the upper metal layer 170 and the bump part 150 may be insignificant. As a result, a problem of the upper metal layer 170 being peeled off from the bump part 150 may occur. For example, the circuit board may expand and/or contract due to thermal stress, which may cause a mechanical reliability problem in which the upper metal layer 170 is peeled off from the bump part 150. In addition, if the internal angle between the upper surface 150T of the bump part 150 and the first slope 150S1 exceeds 160 degrees, a difference between the width of the upper surface 150T of the bump part 150 in the horizontal direction and the width of the lower surface in the horizontal direction may increase. As the difference in width increases, the transmission loss of a signal transmitted through the bump part 150 increases, which may deteriorate the signal transmission characteristics. In addition, if the width of the upper surface 150T becomes excessively small as the difference in width increases, the upper metal layer 170 may not be stably disposed on the bump part 150, and further, a semiconductor device may not be stably coupled on the upper metal layer 170. In addition, if the width of the lower surface of the bump part 150 becomes excessively large as the difference in width increases, it may be difficult to refine a line width and spacing of the bump part 150. As a result, it may be difficult to thin the circuit board, and the volume of the semiconductor package and the electronic product or server including the same may increase.

The second slope 150S2 of the bump part 150 can connect between a lower end of the first slope 150S1 and the lower surface of the bump part 150. The second slope 150S2 can be inclined more than the first slope 150S1 with respect to the upper surface 150T of the bump part 150. In addition, the second slope 150S can be inclined less than the first slope 150S1 with respect to the lower surface of the bump part 150.

Preferably, an internal angle between the upper surface 150T of the bump part 150 and the second slope 150S2 can be smaller than the internal angle between the upper surface 150T and the first slope 150S1. Preferably, the internal angle between the upper surface 150T of the bump part 150 and the second slope 150S2 can be close to 90 degrees.

The internal angle between the upper surface 150T of the bump part 150 and the second slope 150S2 can satisfy a range of 80 degrees to 100 degrees. Preferably, the internal angle between the upper surface 150T of the bump part 150 and the second slope 150S2 can satisfy a range of 82 degrees to 98 degrees. More preferably, the internal angle between the upper surface 150T of the bump part 150 and the second slope 150S2 can satisfy a range of 85 degrees to 95 degrees. If the internal angle between the upper surface 150T of the bump part 150 and the second slope surface 150S2 is out of a range of 80 to 100 degrees, a difference in width between the upper surface 150T and the lower surface of the bump part 150 may increase, and accordingly, signal transmission loss may increase and signal transmission characteristics may deteriorate.

Meanwhile, the first slope 150S1 and the second slope 150S2 of the bump part 150 may be provided by a process of flattening the bump part 150 or a pretreatment process before forming the upper metal layer 170. For example, the embodiment may perform a process of etching the upper surface 150T of the bump part 150 after forming the bump part 150. Through this, the embodiment may enable each of the plurality of first bumps and second bumps of the bump part 150 to have a same thickness and surface height. Through this, the embodiment can minimize the change in the characteristics of the signal transmitted through the bump part 150. For example, impedance matching can be performed by adjusting the thickness and/or width of the bump part 150. At this time, if the plurality of first bumps and second bumps of the bump part 150 have different thicknesses and/or heights due to plating deviations, etc., the impedance characteristics may change accordingly, which may cause electrical reliability problems.

Therefore, the embodiment can improve the adhesion between the bump part 150 and the upper metal layer 170 while preventing changes in the electrical characteristics of the bump part 150.

Meanwhile, a vertical length (e.g., a thickness in the vertical direction, H1) of the bump part 150 satisfies a range of 15 μm to 40 μm. For example, the vertical length H1 of the bump part 150 can satisfy a range of 20 μm to 35 μm. More preferably, for example, the vertical length H1 of the bump part 150 can have a thickness in a range of 22 μm to 32 μm. If the vertical length H1 of the bump part 150 is less than 15 μm, an allowable current of a signal that can be transmitted through the bump part 150 may decrease. If the vertical length H1 of the bump part 150 is less than 15 μm, the semiconductor device may not be stably coupled on the bump part 150. If the vertical length H1 of the bump part 150 exceeds 40 μm, the thickness of the circuit board, the semiconductor package, and the electronic product may increase.

Meanwhile, a vertical length H2 of the first slope 150S1 of the bump part 150 may be greater than the vertical length H3 of the second slope 150S2 of the bump part 150.

The vertical length H2 of the first slope 150S1 of the bump part 150 may satisfy a range of 60% to 80% of the vertical length H1 between the upper surface 150T and the lower surface of the bump part 150. Preferably, the vertical length H2 of the first slope 150S1 of the bump part 150 may satisfy a range of 65% to 78% of the vertical length H1 between the upper surface 150T and the lower surface of the bump part 150. More preferably, the vertical length H2 of the first slope 150S1 of the bump part 150 can satisfy a range of 65% to 75% of the vertical length H1 between the upper surface 150T and the lower surface of the bump part 150.

If the vertical length H2 of the first slope 150S1 of the bump part 150 is less than 60% of the vertical length H1 between the upper surface 150T and the lower surface of the bump part 150, the flattening degree of the bump part 150 may be insufficient, or the effect of increasing the contact area with the upper metal layer 170 may be insufficient. If the vertical length H2 of the first slope 150S1 of the bump part 150 exceeds 80% of the vertical length H1 between the upper surface 150T and the lower surface of the bump part 150, the difference in width between the upper surface 150T and the lower surface of the bump part 150 may increase.

Correspondingly, a vertical length H3 of the second slope 150S2 of the bump part 150 may satisfy a range of 20% to 40% of the vertical length H1 between the upper surface 150T and the lower surface of the bump part 150. Preferably, the vertical length H3 of the second slope 150S2 of the bump part 150 may satisfy a range of 22% to 35% of the vertical length H1 between the upper surface 150T and the lower surface of the bump part 150. More preferably, if the vertical length H3 of the second slope 150S2 of the bump part 150 is out of the range of 25% to 35% of the vertical length H1 between the upper surface 150T and the lower surface of the bump part 150, the effect of increasing the adhesion between the insulating layer 100 and the bump part 150 may be insignificant, or the difference in the width between the upper surface 150T and the lower surface of the bump part 150 may become large.

Meanwhile, at least a part of the first slope 150S1 of the bump part 150 may not be in contact with the insulating layer 100. For example, the first slope 150S1 of the bump part 150 may include an overlapping portion that overlaps the insulating layer 100 in the horizontal direction and a non-overlapping portion that does not overlap the insulating layer 100 in the horizontal direction. In addition, the overlapping portion of the first slope 150S1 of the bump part 150 may not be in contact with the insulating layer 100. For example, the overlapping portion of the first slope 150S1 of the bump part 150 may be spaced apart from an inner wall 110W of the concave part of the insulating layer 100. For example, at least a part of the first slope 150S1 of the bump part 150 may horizontally overlap with the inner wall 110W of the insulating layer 100 and not be in contact with the inner wall 110W. For example, the bump part 150 may have a crevice corresponding to the first slope 150S1. In addition, the first slope 150S1 of the bump part 150 may be in contact with the upper metal layer 170. Through this, the contact area between the upper metal layer 170 and the bump part 150 can be increased, and thus the electrical reliability and/or mechanical reliability of the circuit board can be improved.

In the embodiment, the bump part 150 includes a tapered slope, and thus the semiconductor device can be prevented from being coupled in a tilted state due to a height difference between the first bump 151 and the second bump 152 of the bump part 150. Through this, the embodiment can minimize the signal transmission loss of the circuit board and the semiconductor package caused by the height difference. In addition, the embodiment can solve the change in impedance characteristics that changes due to the height difference. In addition, the embodiment can enable the semiconductor device mounted on the circuit board to operate stably. Through this, the embodiment can further improve the mechanical reliability and physical reliability of the semiconductor package and the electronic product including the same, and thus the product reliability can be further improved.

Meanwhile, the via electrode VE can have a tapered slope whose width changes along the vertical direction. At this time, inclination directions of the via electrodes VE disposed in the insulating layer 100 may be the same as each other. In addition, a slope VES of a side surface of the via electrode VE may be the same as an inclination direction of the first slope 150S1 of the bump part 150. However, an angle of the slope VES of the side surface of the via electrode VE may be different from the angle of the first slope 150S1 of the pad 151.

The upper metal layer 170 may be provided to cover the first slope 150S1 of the bump part 150. At least a portion of the first slope 150S1 may horizontally overlap with the insulating layer 100. For example, the upper metal layer 170 may be provided within the crevice of the bump part 150, and accordingly, at least a portion of the upper metal layer 170 may horizontally overlap with the inner wall 110W of the insulating layer 100 and the first slope 150S1 of the bump part 150. Through this, the embodiment can improve the contact area between the upper metal layer 170 and the bump part 150, and further, can solve the problem of the upper metal layer 170 being peeled off from the bump part 150. Furthermore, the embodiment can prevent the intermetallic compound from diffusing between the gap between the insulating layer 100 and the side surface of the bump part 150, thereby improving the mechanical reliability and physical reliability of the semiconductor package.

A width of the upper metal layer 170 in the horizontal direction can be larger than a width of the bump part 150 in the horizontal direction. Accordingly, the upper metal layer 170 can include a first portion 170-1 that vertically overlaps the bump part 150 and a second portion 170-2 that does not vertically overlap the bump part 150. The first portion 170-1 of the upper metal layer 170 can be disposed on the bump part 150 and can be in contact with the upper surface 150T and the first slope 150S1 of the bump part 150. In addition, the second portion 170-2 of the upper metal layer 170 may be disposed on the insulating layer 100 and may be in contact with the upper surface 110T of the insulating layer 100. The side surface 170S of the second portion 170-2 of the upper metal layer 170 may have a slope. For example, the side surface 170S of the second portion 170-2 of the upper metal layer 170 may have a slope that is inclined in a same direction as the first slope 150S1 of the bump part 150. In addition, the width of the upper metal layer 170 in the horizontal direction may be larger than a width of an opening 130R of the third insulating layer 130. Therefore, the side surface 170S of the upper metal layer 170 may be covered with the third insulating layer 130. At this time, the side surface 170S of the upper metal layer 170 may have a slope whose width gradually increases from the upper surface of the upper metal layer 170 toward the lower surface, thereby increasing the contact area between the upper metal layer 170 and the third insulating layer 130. Therefore, the embodiment may solve the problem of the third insulating layer 130 being peeled off from the insulating layer 100 and/or the upper metal layer 170.

Meanwhile, referring to FIG. 5, the third insulating layer 130 may be disposed on the insulating layer 100. The third insulating layer 130 may include an opening that vertically overlaps the bump part 150.

In the circuit board according to the third embodiment of FIG. 5, the upper metal layer 170 may be disposed after the third insulating layer 130 is laminated.

The width of the opening of the third insulating layer 130 in the horizontal direction may be greater than the width of the bump part 150 in the horizontal direction. Accordingly, the third insulating layer 130 may not vertically overlap with the bump part 150. For example, an inner wall 130IW of the opening of the third insulating layer 130 and an inner wall 110W of the insulating layer 100 may have a step in the horizontal direction. For example, the opening of the third insulating layer 130 may be provided with a NSMD (Non-Solder Mask Defined).

The upper metal layer 170 may be disposed on the bump part 150. The upper metal layer 170 may be disposed on the third insulating layer 130. For example, the upper metal layer 170 may protrude above the third insulating layer 130 while filling the opening of the third insulating layer 130. The upper metal layer 170 may be divided into a plurality of regions along the vertical direction.

The upper metal layer 170 may include a first region 170-1 protruding on the third insulating layer 130. A width of the first region 170-1 of the upper metal layer 170 in the horizontal direction may be larger than the width of the opening of the third insulating layer 130 in the horizontal direction. Therefore, at least a portion of the first region 170-1 of the upper metal layer 170 may be in contact with the upper surface of the third insulating layer 130. A side surface 170S1 of the first region 170-1 of the upper metal layer 170 may have a slope in which the width gradually increases from the upper surface toward the lower surface of the upper metal layer 170.

The upper metal layer 170 may include a second region 170-2 disposed in the opening of the third insulating layer 130. The side surface 170S2 of the second region 170-2 of the upper metal layer 170 may contact the inner wall 130IW of the opening 130R of the third insulating layer 130.

The upper metal layer 170 may include a third region 170-3 filling the crevice of the bump part 150. A side surface 170S3 of the third region 170-3 of the upper metal layer 170 may contact the inner wall 110W of the insulating layer 100.

Therefore, the side surface of the upper metal layer 170 may have a step in the horizontal direction. For example, the side surface 170S1 of the first region 170-1, the side surface 170S 2 of the second region 170-2, and the side surface 170S1 of the third region 170-3 of the upper metal layer 170 may have a step.

For example, the width of the first region 170-1 of the upper metal layer 170 in the horizontal direction, the width of the second region 170-2 in the horizontal direction, and the width of the third region 170-3 in the horizontal direction may be different from each other. Therefore, the side surface of the upper metal layer 170 may have a step. In the embodiment, the contact area between the upper metal layer 170 and the third insulating layer 130 and the bump part 150 can be further improved by the side surface of the upper metal layer 170 having steps, thereby solving the problem of the upper metal layer 170 being peeled off.

In addition, the embodiment can further increase a distance between the intermetallic compound that can diffuse along the side surface of the upper metal layer 170 and the bump part 150 by having a step on the side of the upper metal layer 170, and can more efficiently solve the problem of electrical reliability and mechanical reliability degradation that can be caused by the intermetallic compound.

In addition, the upper metal layer 170 of the embodiment can improve the bonding between the upper metal layer 170 and the terminal of the semiconductor device by protruding and being disposed on the third insulating layer 130. For example, the embodiment can perform thermal compression bonding to reduce the volume of a bonding member such as solder. At this time, the upper metal layer 170 can improve a positional alignment between a terminal of the semiconductor device and the upper metal layer 170 in the thermal compression bonding process by protruding and being disposed on the third insulating layer 130.

Meanwhile, referring to FIG. 6, the third insulating layer 130 may be disposed on the insulating layer 100. The third insulating layer 130 may include an opening that vertically overlaps the bump part 150.

At this time, the upper metal layer 170 in one embodiment may be formed before the third insulating layer 130 is disposed, and the upper metal layer 170 in another embodiment may be formed after the third insulating layer 130 is disposed.

A width of the opening 130R of the third insulating layer 130 in the horizontal direction may be larger than the width of the bump part 150 in the horizontal direction. Accordingly, the third insulating layer 130 may not vertically overlap the bump part 150. For example, an inner wall 130IW of the opening of the third insulating layer 130 and an inner wall 110W of the insulating layer 100 may have a step.

The upper metal layer 170 may be disposed on the bump part 150. The upper metal layer 170 may be disposed on the insulating layer 100. At this time, the upper metal layer 170 may not be disposed on the third insulating layer 130. For example, the upper metal layer 170 may not overlap the third insulating layer 130 in the vertical direction.

For example, the side surface 170S1 of the upper metal layer 170 may not in contact with the inner wall 130IW of the opening 130R of the third insulating layer 130. For example, the side surface 170S1 of the upper metal layer 170 may be spaced apart from the inner wall 130IW of the opening 130R of the third insulating layer 130 in the horizontal direction. Through this, the embodiment can increase the volume of a bonding member such as a solder without increasing the thickness of the semiconductor package. In addition, the embodiment can solve the problem of an electric short in which a plurality of adjacent upper metal layers 170 come into contact with each other due to pressure generated during the mounting process of the semiconductor device. For example, a space can be provided between the side surface 170S1 of the upper metal layer 170 and the inner wall 130IW of the opening 130R of the third insulating layer 130, and the space can function as a dam to prevent overflow of the bonding member generated by the pressure. Through this, the embodiment can stably bond the semiconductor device on the upper metal layer 170, and thereby improve the mechanical reliability and/or electrical reliability of the semiconductor package.

In addition, an upper surface of the upper metal layer 170 can be positioned higher than the upper surface of the third insulating layer 130. Through this, the embodiment can improve the positional alignment between the upper metal layer 170 and the terminal of the semiconductor device.

Meanwhile, referring to FIG. 7, the third insulating layer 130 can have an opening having a width in the horizontal direction smaller than the width in the horizontal direction of the bump part 150. In addition, the third insulating layer 130 can be formed before the upper metal layer 170 is formed in a manufacturing process of the circuit board.

That is, the third insulating layer 130 can be formed before the upper metal layer 170 is formed, and accordingly, a crevice of the bump part 150 can be filled by the third insulating layer 130.

For example, the third insulating layer 130 can be disposed on the insulating layer 100 and the bump part 150. The lower surface of the third insulating layer 130 may include a first lower surface that contacts the upper surface of the insulating layer 100, and a second lower surface that contacts the bump part 150.

In addition, the second lower surface of the third insulating layer 130 may include a portion that contacts the first slope 150S1 of the bump part 150. For example, the second lower surface of the third insulating layer 130 may have a slope corresponding to the first slope 150S1 of the bump part 150. Through this, the embodiment may increase the contact area between the third insulating layer 130 and the bump part 150, and thus improve the bonding strength therebetween.

In addition, the second lower surface of the third insulating layer 130 may include a portion that contacts the upper surface of the bump part 150, but is not limited thereto.

For example, the width of the opening of the third insulating layer 130 in the horizontal direction may be smaller than the width of the upper surface 150T of the bump part 150 in the horizontal direction, and thus, at least a portion of the second lower surface of the third insulating layer 130 may be in contact with the upper surface 150T of the bump part 150.

In addition, the width of the opening of the third insulating layer 130 in the horizontal direction according to another embodiment may be larger than the width of the upper surface 150T of the bump part 150 in the horizontal direction, and thus, the second lower surface of the third insulating layer 130 may be in contact with at least a portion of the first slope 150S1 of the bump part 150 without being in contact with the upper surface 150T of the bump part 150. At this time, at least a part of the first slope 150S1 of the bump part 150 may contact the upper metal layer 170 without contacting the third insulating layer 130.

Meanwhile, the upper metal layer 170 may be disposed on the bump part 150. The upper metal layer 170 may protrude on the third insulating layer 130.

The upper metal layer 170 may include a first region 170-1 protruding on the third insulating layer 130 and a second region 170-2 disposed in the opening of the third insulating layer 130. A width of the first region 170-1 of the upper metal layer 170 in the horizontal direction may be larger than a width of the opening of the third insulating layer 130 in the horizontal direction. Accordingly, at least a part of the first region 170-1 of the upper metal layer 170 may overlap with the third insulating layer 130 in the vertical direction.

Through this, the embodiment may reduce the width of the upper metal layer 170 in the horizontal direction by arranging the upper metal layer 170 after the opening of the third insulating layer 130 is formed. Therefore, the embodiment may increase a spacing between the plurality of adjacent conductive pads. Accordingly, the embodiment may more efficiently prevent a circuit short problem in which the plurality of conductive pads electrically contact each other in a process of mounting a semiconductor device. Therefore, the embodiment may further improve the electrical reliability of the semiconductor package.

Meanwhile, referring to FIG. 8, the third insulating layer 130 may be disposed on the insulating layer 100 and may include an opening 130R that vertically overlaps with the upper metal layer 170.

An inner wall of the opening 130R of the third insulating layer 130 may include a portion having a curved surface. The inner wall of the opening 130R of the third insulating layer 130 may include a first inner wall 130IW1 adjacent to the upper surface of the third insulating layer 130 and having a width that decreases toward the lower surface of the third insulating layer 130. The first inner wall 130IW1 of the third insulating layer 130 may not be in contact with the upper metal layer 170. The first inner wall 130IW1 of the third insulating layer 130 has a curved surface having a specific radius of curvature.

A lowermost end of the first inner wall 130IW1 of the opening 130R of the third insulating layer 130 may be positioned lower than the upper surface of the upper metal layer 170. Accordingly, at least a portion of the side surface of the upper metal layer 170 may not be covered by the third insulating layer 130. For example, at least a portion of the side surface 170S of the upper metal layer 170 may horizontally overlap the first inner wall 130IW1. Through this, the embodiment can allow the bonding member disposed on the upper metal layer 170 to come into contact with at least a portion of the side surface 170S of the upper metal layer 170. Through this, the embodiment can increase the contact area between the upper metal layer 170 and the connecting member, and thereby improve the mutual bonding strength. Therefore, the embodiment can stably couple the semiconductor device on the upper metal layer 170, and thus can stably operate the semiconductor device.

The inner wall of the opening 130R of the third insulating layer 130 can include a second inner wall 130IW2 adjacent to the lower surface of the third insulating layer 130. The second inner wall 130IW2 of the opening 130R of the third insulating layer 130 can contact the upper metal layer 170. For example, the second inner wall 130IW2 of the opening 130R of the third insulating layer 130 can have a slope corresponding to the slope of the side surface 170S of the upper metal layer 170.

Accordingly, in the embodiment, at least a portion of the side surface 170S of the upper metal layer 170 may not be covered with the third insulating layer 130, and a remaining portion may be covered with the third insulating layer 130. Through this, the embodiment can effectively prevent an intermetallic compound formed by the bonding member from diffusing into the bump part 150 while improving the contact area between the upper metal layer 170 and the connection member. Through this, the embodiment can improve the mechanical reliability and/or electrical reliability of the circuit board.

The semiconductor package of the embodiment include a first insulating layer including a cavity, a connection member disposed in the cavity, and a second insulating layer disposed on the connection member. The second insulating layer can stably fix the connection member while relieving thermal stress acting on the semiconductor package, thereby minimizing damage transmitted to the connection member. Through this, the embodiment can prevent thermal stress from being transmitted to the connection member through the second insulating layer. For example, the second insulating layer can serve as a buffer to buffer stress. Through this, the embodiment can stably couple the connection member to the semiconductor package, thereby improving physical reliability and mechanical reliability of the connection member.

Specifically, the second insulating layer is provided to surround a pad part of the connection member and a bonding part disposed on the pad part. In addition, the second insulating layer is provided to surround at least a portion of the bump part disposed on the bonding part. Through this, the second insulating layer of the embodiment functions to buffer stress transmitted to the bump part, the pad part, and the bonding part. Therefore, the embodiment prevents cracks from occurring in the bonding part due to stress. Through this, the embodiment can improve the electrical connection reliability between the pad part, the bonding part, and the bump part. Therefore, the embodiment can stably connect a plurality of semiconductor devices by the connection member, thereby improving the operational reliability of the plurality of semiconductor devices.

In addition, a width of the second insulating layer in a horizontal direction is larger than a width of the connection member in the horizontal direction. Through this, the embodiment can maximize the effect of the buffer function through the second insulating layer, thereby further improving the physical reliability and electrical reliability of the semiconductor package.

In addition, the second insulating layer can include an extension part. In this case, the extension part of the second insulating layer can extend toward a side surface of the connection member. For example, the extension part of the second insulating layer can cover at least a part of the side surface of the connection member. Through this, the embodiment can enable the connection member to be more stably disposed in the cavity, and further minimize the stress transmitted to the connection member. In addition, when air is filled around the side surface of the connection member, the air may expand due to heat generated from the semiconductor device or the semiconductor package, which may cause mechanical damage such as cracks in the semiconductor package. Therefore, if the second insulating layer does not include the extension part, the side surface of the connection member can be covered with another material to improve the operational reliability.

Meanwhile, the second insulating layer can have a step with the first insulating layer. For example, an upper surface of the second insulating layer can be positioned lower than an upper surface of the first insulating layer. Through this, the embodiment can improve a contact area with the third insulating layer disposed on the first insulating layer and the second insulating layer, thereby solving a problem of the third insulating layer being peeled off from the first insulating layer and/or the second insulating layer. In addition, the first insulating layer and the second insulating layer can have different coefficients of thermal expansion, and thus at least one can expand or contract more than at least the other. At this time, the embodiment can solve the problem of peeling between the first insulating layer and the second insulating layer caused by expansion or contraction by making the upper surface of the second insulating layer and the upper surface of the first insulating layer have a step, thereby improving the mechanical reliability of the semiconductor package.

In addition, the semiconductor package of the embodiment includes a bump part disposed on the first and second insulating layers. The bump part includes a first bump protruding on the first insulating layer while penetrating at least a portion of the first insulating layer. In addition, the bump part includes a second bump protruding on the second insulating layer while penetrating at least a portion of the second insulating layer. At this time, a width of the second bump in the horizontal direction may be smaller than a width of the first bump in the horizontal direction. That is, at least a portion of the second bump may be embedded in the second insulating layer, thereby making the width of the second bump smaller than the width of the first bump. Through this, the embodiment may reduce a pitch of the pad part provided in the connection member, thereby reducing a volume of the connection member. Therefore, the embodiment may reduce a volume of the semiconductor package.

In addition, a side surface of the bump part including the first and second bumps may include a first slope that is adjacent to the upper surface of the bump part and increases in width toward the lower surface of the bump part and a second slope different from the first slope. The first slope and the second slope can be provided by a flattening process or a pretreatment process of the bump part. For example, the bump part can include a plurality of first bumps and second bumps, and each of the first and second bumps can have a first slope and a second slope. Through this, the embodiment can allow the bump parts to have a uniform height, thereby minimizing the height deviation therebetween. Furthermore, the embodiment can allow the bump parts including a plurality of bumps to have a same height. Through this, the embodiment can allow a semiconductor device to be stably disposed on a bump part, thereby allowing the semiconductor device to operate smoothly. Therefore, the embodiment can improve the operating characteristics of the semiconductor package and an electronic product including the same.

In addition, the first slope of the bump part can be covered by the third insulating layer or an upper metal layer. The embodiment can make the first slope of the bump part come into contact with the third insulating layer or the upper metal layer, thereby increasing a contact area therebetween. Through this, the embodiment can increase the bonding strength of the bump part and the third insulating layer or the upper metal layer, and can solve the problem of them being separated from each other. Through this, the embodiment can improve the mechanical reliability and/or electrical reliability of the circuit board and the semiconductor package including the same.

In addition, the first slope of the bump part can include a portion that overlaps the first or second insulating layer and does not contact the first or second insulating layer. In addition, at least a part of the first slope can be covered by the upper metal layer or the third insulating layer. Through this, the embodiment can prevent a bonding member such as solder from spreading into the bump part. In addition, the embodiment can allow an intermetallic compound formed by the connecting member to be provided far from the first wiring electrode, and through this, can solve the problem of cracking or deterioration of electrical characteristics of the bump part that may be caused by the intermetallic compound.

In addition, the embodiment can improve the signal transmission characteristics of the circuit board and the semiconductor package accordingly by making the bump parts have a uniform height. For example, the embodiment can minimize signal transmission loss caused by a height difference of a bump part. Furthermore, the embodiment can prevent a change in impedance characteristics that changes due to a height difference. Through this, the embodiment can further improve the mechanical reliability and physical reliability of a semiconductor package and an electronic product including the same.

Hereinafter, a method for manufacturing a circuit board illustrated in FIG. 2a will be described.

FIGS. 9 to 23 are drawings showing a manufacturing method of the circuit board illustrated in FIG. 2a in order of processes.

Referring to FIG. 9, an embodiment prepares an insulating member that serves as a basis for manufacturing a circuit board. The insulating member may be a carrier board CB. For example, the carrier board CB may include a carrier insulating layer CB1 and a carrier metal layer CB2 and CB3. The carrier metal layer CB2 and CB3 may have a two-layer structure. For example, the carrier metal layers CB2 and CB3 may be provided as metal layers including different metal materials. A first carrier metal layer CB2 may be disposed under the carrier insulating layer CB1. The first carrier metal layer CB2 may include a first metal material. The first metal material may include copper. The carrier insulating layer CB1 and the first carrier metal layer CB2 may be a copper clad laminate (CCL). A second carrier metal layer CB3 may be disposed under the first carrier metal layer CB2. The second carrier metal layer CB3 may include a second metal material different from the first metal material. The second metal material may include nickel. For example, the second carrier metal layer CB2 may be formed of a metal material that is not etched by an etchant used to etch the first metal material. Through this, the embodiment can prevent the bump part 150 from being etched in a seed layer etching process included in a manufacturing process of the circuit board. Through this, the embodiment can minimize a height deviation of a plurality of first bumps 151 and second bumps 152 of the bump part 150. In FIG. 9, the first carrier metal layer CB2 and the second carrier metal layer CB3 are illustrated as being disposed on one surface of the carrier insulating layer CB1, but this is not limited thereto. For example, the first carrier metal layer CB2 and the second carrier metal layer CB3 may be disposed on both surfaces of the carrier insulating layer CB1. In this case, a process of manufacturing multiple circuit boards may be simultaneously performed on both sides of the carrier insulating layer CB1.

Referring to FIG. 10, the embodiment may perform a process of forming a bump part 150 on the second carrier metal layer CB3. The bump part 150 may be formed by performing electrolytic plating on the second carrier metal layer CB3 as a seed layer.

Referring to FIG. 11, the embodiment may perform a process of laminating the first insulating layer 110 on the second carrier metal layer CB3. For example, the embodiment may perform a process of forming a fourth layer 114 of the first insulating layer 110 on the second carrier metal layer CB3. The first insulating layer 110 may be disposed to completely fill the bump part 150.

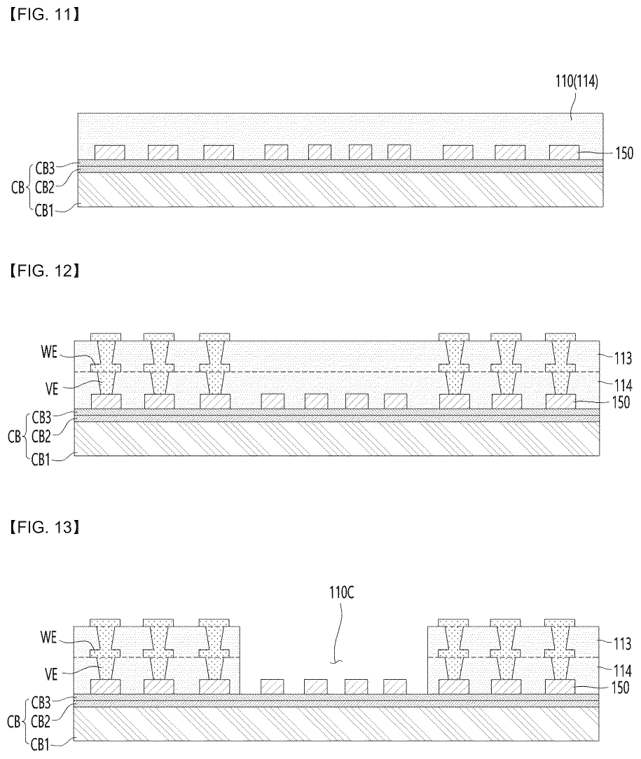

Referring to FIG. 12, the embodiment may perform a process of forming a via electrode VE and a wiring electrode WE on the fourth layer 114 of the first insulating layer 110. In addition, the embodiment may perform a process of forming a third layer 113 on the fourth layer 114 of the first insulating layer 110. In addition, the embodiment may perform a process of forming a via electrode VE and a wiring electrode WE on the third layer 113.

Referring to FIG. 13, the embodiment may perform a process of forming a cavity 100C by processing the first insulating layer 110. The cavity 100C may overlap with the second bump 152 among the bump parts 150 in the vertical direction. Therefore, the second bump 152 may expose through the cavity 100C.

Referring to FIG. 14, the embodiment may perform a process of forming a second insulating layer 120 in the cavity 100C. The second insulating layer 120 may have different properties from the first insulating layer 110. For example, the second insulating layer 120 may be a non-conductive adhesive material, but is not limited thereto. Preferably, the second insulating layer 120 may include an insulating material capable of thermocompression bonding (TC bonding).

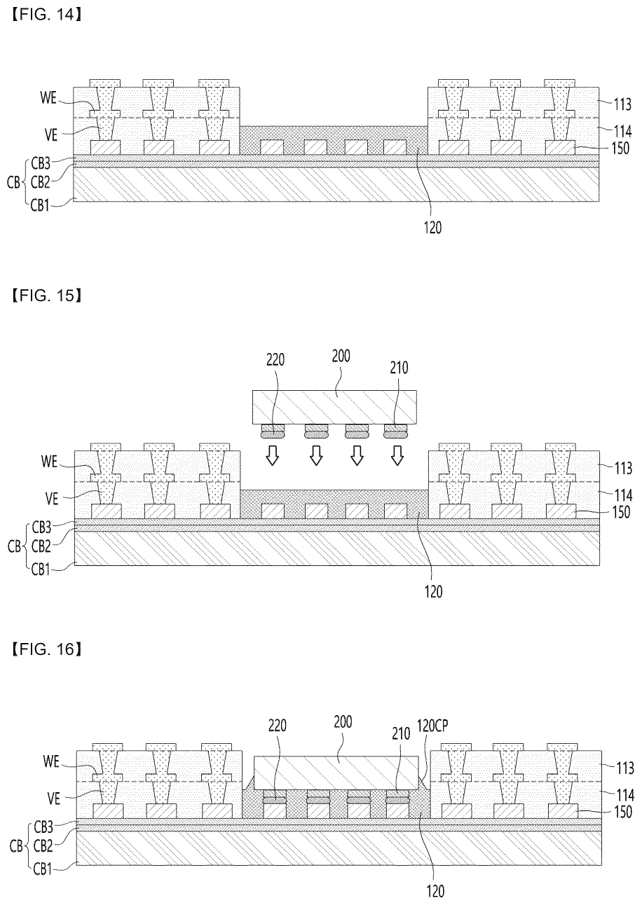

Referring to FIG. 15, the embodiment can perform a process of electrically coupling the pad part 210 of the connection member 200 and the second bump 152 of the bump part 150 with each other while arranging the bonding part 220 under the pad part 210 of the connection member 200. At this time, the embodiment can recognize an arrangement position of the connection member 200 by utilizing some of wiring electrodes disposed at an outermost part of the circuit board as guide points GP.

Referring to FIG. 16, the embodiment can embed the pad part 210 of the connection member 200 in the second insulating layer 120 by applying pressure while applying temperature in a bonding facility. At this time, the second insulating layer 120 can be extended to the side surface of the connection member 200 by the pressure, and thus can be provided with an extension part 120CP that surrounds at least a part of the side surface of the connection member 200.

Referring to FIG. 17, the embodiment can perform an additional lamination process on the third layer 113 of the first insulating layer 110 to manufacture a multilayer circuit board.

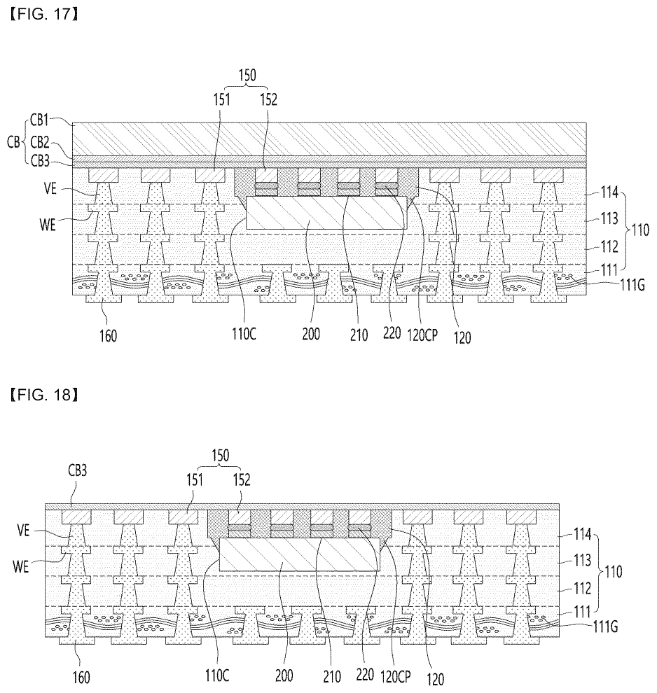

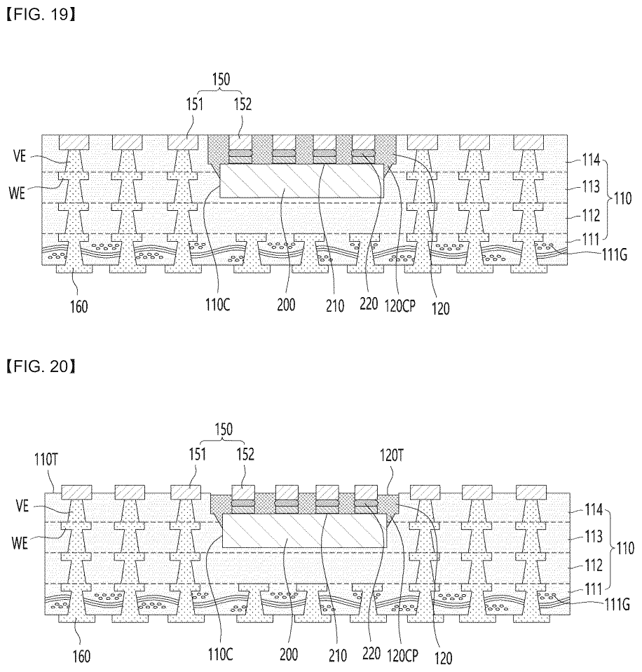

Referring to FIG. 18, the embodiment can perform a process of removing the carrier board CB. To this end, the embodiment can perform a process of removing the carrier insulating layer CB1. Thereafter, the embodiment can perform a process of removing the first carrier metal layer CB2. At this time, the second carrier metal layer CB3 includes a different metal material from the first carrier metal layer CB2, and thus, it may not be removed in the process of removing the first carrier metal layer CB2.

Referring to FIG. 19, the embodiment can perform a process of removing the second carrier metal layer CB3 by etching. At this time, the second carrier metal layer CB3 includes a different metal material from the bump part 150, and thus, the bump part 150 may not be removed in a process of removing the second carrier metal layer CB3.

Referring to FIG. 20, the embodiment may perform a process of removing a portion of the upper surface of the first insulating layer 110 and the upper surface of the second insulating layer 120 by performing a plasma etching process. At this time, the first insulating layer 110 and the second insulating layer 120 may include different insulating materials. For example, a content of the filler provided in the second insulating layer 120 may be smaller than a content of the filler provided in the first insulating layer 110. Accordingly, the upper surface 110T of the first insulating layer 110 and the upper surface 120T of the second insulating layer 120 after the etching process may have a step. For example, the upper surface 110T of the first insulating layer 110 may be positioned higher than the upper surface 120T of the second insulating layer 120.

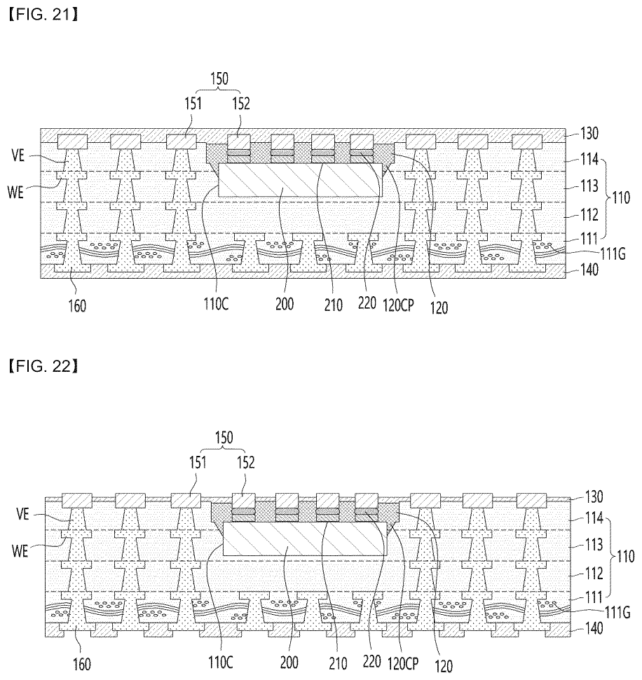

Referring to FIG. 21, the embodiment may perform a process of forming a third insulating layer 130 on the first insulating layer 110 and the second insulating layer 120 and a process of forming a fourth insulating layer 140 under the first insulating layer 110.

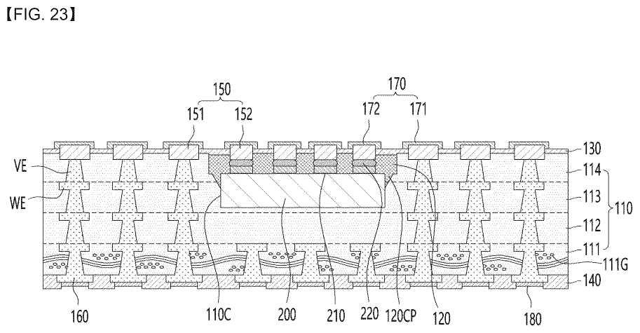

Referring to FIG. 22, the embodiment may perform a process of reducing a thickness of the third insulating layer 130. Through this, the upper surface of the third insulating layer 130 may be positioned lower than the upper surface of the bump part 150. In addition, the embodiment may perform a process of forming at least one opening by exposing and developing the fourth insulating layer 140.

Referring to FIG. 23, the embodiment may perform a process of forming an upper metal layer 170 on a bump part 150 and forming a lower metal layer 180 under a terminal electrode 160.

On the other hand, when the circuit board having the above-described characteristics of the invention is used in an IT device or home appliance such as a smart phone, a server computer, a TV, and the like, functions such as signal transmission or power supply can be stably performed. For example, when a circuit board having the features of the present invention performs a semiconductor package function, the circuit board can function to safely protect the semiconductor chip from external moisture or contaminants, or alternatively, it is possible to solve problems of leakage current, electrical short circuit between terminals, and electrical opening of terminals supplied to the semiconductor chip. In addition, when the function of signal transmission is in charge, it is possible to solve the noise problem. Through this, the circuit board having the above-described characteristics of the invention can maintain the stable function of the IT device or home appliance, so that the entire product and the circuit board to which the present invention is applied can achieve functional unity or technical interlocking with each other.

When the circuit board having the characteristics of the invention described above is used in a transport device such as a vehicle, it is possible to solve the problem of distortion of a signal transmitted to the transport device, or alternatively, the safety of the transport device can be further improved by safely protecting the semiconductor chip that controls the transport device from the outside and solving the problem of leakage current or electrical short between terminals or the electrical opening of the terminal supplied to the semiconductor chip. Accordingly, the transportation device and the circuit board to which the present invention is applied can achieve functional integrity or technical interlocking with each other.

The characteristics, structures and effects described in the embodiments above are included in at least one embodiment but are not limited to one embodiment. Furthermore, the characteristics, structures, and effects and the like illustrated in each of the embodiments may be combined or modified even with respect to other embodiments by those of ordinary skill in the art to which the embodiments pertain. Thus, it should be construed that contents related to such a combination and such a modification are included in the scope of the embodiment.

The description has been focused on the embodiment, but it is merely illustrative and does not limit the embodiment. A person skilled in the art to which the embodiment pertains may appreciate that various modifications and applications not illustrated above are possible without departing from the essential features of the embodiment. For example, each component particularly represented in the embodiment may be modified and implemented. In addition, it should be construed that differences related to such changes and applications are included in the scope of the embodiment defined in the appended claims.

1. A circuit board comprising:
a first insulating layer including a cavity;
a connection member disposed in the cavity; and
a second insulating layer disposed on the connection member and including a material different from a material of the first insulating layer,
wherein a width of the second insulating layer is larger than a width of the connection member.

2. The circuit board of claim 1, wherein the second insulating layer includes a non-conductive adhesive material.

3. The circuit board of claim 1, wherein an upper surface of the first insulating layer and the upper surface of the second insulating layer have a step.

4. The circuit board of claim 3, wherein the upper surface of the second insulating layer is positioned lower than the upper surface of the first insulating layer.

5. The circuit board of claim 3, further comprising:
a third insulating layer disposed on the first insulating layer and the second insulating layer,
wherein a lower surface of the third insulating layer includes a first lower surface in contact with the upper surface of the first insulating layer, and a second lower surface in contact with the upper surface of the second insulating layer, and
wherein the first and second lower surfaces of the third insulating layer have a step.

6. The circuit board of claim 5, further comprising:
a bump part including a first bump disposed on the first insulating layer and a second bump disposed on the second insulating layer,
wherein the first bump does not overlap the connection member in a vertical direction, and
wherein the second bump overlaps the connection member in the vertical direction and overlaps the first bump in a horizontal direction.

7. The circuit board of claim 6, wherein at least one of upper and lower surfaces of the first bump is positioned on a same plane as at least one of upper and lower surfaces of the second bump.

8. The circuit board of claim 6, wherein the connection member includes:
an insulating member;
a pad part disposed on the insulating member; and
a bonding part disposed on the pad part and electrically connecting the second bump and the pad part, and
wherein the second insulating layer embeds the pad part and the bonding part.

9. The circuit board of claim 8, wherein the second insulating layer includes an extension part extending toward a side surface of the insulating member of the connection member and covering at least a portion of the side surface of the insulating member.

10. The circuit board of claim 6, wherein a width of the second bump in a horizontal direction is smaller than a width of the first bump in the horizontal direction.

11. The circuit board of claim 6, wherein the first insulating layer has a first concave part that is concave from the upper surface of the first insulating layer toward a lower surface of the first insulating layer,
wherein the first bump is disposed in the first concave part and includes a first slope whose width increases toward the lower surface of the first insulating layer, and
wherein an upper surface of the first bump is located higher than the upper surface of the first insulating layer based on the lower surface of the first insulating layer.

12. The circuit board of claim 11, wherein the second insulating layer has a second concave part that is concave from an upper surface of the second insulating layer toward a lower surface of the second insulating layer,
wherein the second bump is disposed in second first concave part and includes a second slope whose width increases toward the lower surface of the second insulating layer, and
wherein an upper surface of the second bump is located higher than the upper surface of the second insulating layer based on the lower surface of the second insulating layer.

13. The circuit board of claim 12, wherein the first slope and the second slope are inclined in a same direction and have a same angle.

14. The circuit board of claim 12, further comprising:
a first upper metal layer disposed on the first bump; and
a second upper metal layer disposed on the second bump.

15. The circuit board of claim 14, wherein the first slope of the first bump has a separation portion overlapping the first insulating layer in a horizontal direction and spaced apart from an inner wall of the first concave part of the first insulating layer,

16. The circuit board of claim 15, wherein the second slope of the second bump has a separation portion overlapping the second insulating layer in the horizontal direction and spaced apart from an inner wall of the second concave part of the second insulating layer.

17. The circuit board of claim 16, wherein the third insulating layer is disposed on the first insulating layer and the second insulating layer, and contacts the separation portion of the first bump and the separation portion of the second bump.

18. The circuit board of claim 17, wherein the first upper metal layer protrudes on the third insulating layer while contacting the separation portion of the first bump.

19. The circuit board of claim 17, wherein the second upper metal layer protrudes on the third insulating layer while contacting the separation portion of the second bump.

20. A semiconductor package comprising:
a circuit board according to claim 19; and
a semiconductor device disposed on the circuit board,
wherein the semiconductor device includes a first semiconductor device and a second semiconductor device spaced apart in a horizontal direction, and
wherein each of the first upper metal layer and the second upper metal layer includes a first group connected to the first semiconductor device and a second group connected to the second semiconductor device.
